(19) United States
(12) Patent Application Publication
(10) Pub. No.: US 2026/0129885 A1
(43) Pub. Date: May 7, 2026

(54) INTEGRATED CIRCUIT DEVICES INCLUDING HIGH-DENSITY CAPACITORS

(71) Applicant: Samsung Electronics Co., Ltd., Suwon-si (KR)

(72) Inventors: Hyo Jong Shin, Mechanicville, NY (US); Beomjin Park, Halfmoon, NY (US); Jongmin Shin, Schenectady, NY (US); Young Gook Park, Rensselaer, NY (US); Kang-ill Seo, Springfield, VA (US)

(21) Appl. No.: 19/237,361

(22) Filed: Jun. 13, 2025

Related U.S. Application Data
(60) Provisional application No. 63/716,473, filed on Nov. 5, 2024.

(51) Int. Cl. H10D 1/66; H10D 84/00

(52) U.S. Cl. CPC H10D 1/66; H10D 84/217

(57) ABSTRACT

An integrated circuit device includes a substrate, and a metal-oxide-semiconductor capacitor (MOSCAP) on the substrate. The MOSCAP includes a lower semiconductor device on the substrate, the lower semiconductor device including a pair of lower source/drain regions and a lower gate structure between the pair of lower source/drain regions, and an upper semiconductor device on the lower semiconductor device, the upper semiconductor device including a pair of upper source/drain regions and an upper gate structure between the pair of upper source/drain regions. The lower gate structure is electrically connected to both of the pair of upper source/drain regions.

### RELATED APPLICATIONS

The present application claims the benefit of U.S. Provisional Patent Application Ser. No. 63/716,473, filed on Nov. 5, 2024, entitled INTEGRATED CIRCUIT DEVICES AND METHODS OF FORMING THE SAME, the disclosure of which is hereby incorporated herein in its entirety by reference.

### TECHNICAL FIELD

The present disclosure generally relates to the field of integrated circuit devices and, more particularly, to integrated circuit devices including high-density capacitors.

### BACKGROUND OF THE INVENTION

The size of transistors in integrated circuit (IC) devices has continued to decrease to down-scale logic elements. This has resulted in the development of gate-all-around (GAA) structures such as multi-bridge channel field-effect transistors (MBCFETs™) and nanosheet FETs (NSFETs). Moreover, as technology to increase transistor density has continued to develop, three-dimensional (3D) device structures, such as stacked transistors, are under consideration.

A stacked transistor (or a “transistor stack”) may include a first transistor and a second transistor. The first transistor may be a first type of transistor (e.g., an n-type metal-oxide-semiconductor (NMOS) transistor) and the second transistor may be a second type of transistor (e.g., a p-type metal-oxide-semiconductor (PMOS) transistor). The first and second types of transistors may be complementary to each other, and thus may be part of a complementary metal-oxide-semiconductor (CMOS) structure. The first and second transistors may be stacked in any order (e.g., first on top of second, or second on top of first), thereby resulting in a stack comprising an upper transistor and a lower transistor.

### SUMMARY OF THE INVENTION

An integrated circuit device, according to some embodiments herein, may include a substrate, and a metal-oxide-semiconductor capacitor (MOSCAP) on the substrate, the MOSCAP comprising a lower semiconductor device on the substrate, the lower semiconductor device comprising a pair of lower source/drain regions and a lower gate structure between the pair of lower source/drain regions, and an upper semiconductor device on the lower semiconductor device, the upper semiconductor device comprising a pair of upper source/drain regions and an upper gate structure between the pair of upper source/drain regions. The lower gate structure may be electrically connected to both of the pair of upper source/drain regions.

An integrated circuit device, according to some embodiments herein, may include a substrate, a frontside metal-oxide-metal capacitor (MOMCAP) on a first surface of the substrate, and a backside MOMCAP on a second surface of the substrate opposite the first surface, the backside MOMCAP electrically connected to the frontside MOMCAP.

An integrated circuit device, according to some embodiments herein, may include a substrate, a metal-oxide-semiconductor capacitor (MOSCAP) on a first surface of the substrate, and a backside metal-oxide-metal capacitor (MOMCAP) on a second surface of the substrate opposite the first surface, the backside MOMCAP electrically connected to the MOSCAP.

Example embodiments of the present application result, in part, from the realization that it may be advantageous to provide one or more high-density capacitors in an integrated circuit device by modifying the existing architecture used to form three-dimensional (3D) stacked transistors, such as 3D stacked field-effect transistors (3DSFETs), in the integrated circuit device, to thereby simplify a fabrication process for the high-density capacitors and reduce fabrication costs associated therewith. For example, the high-density capacitors may function as decoupling capacitors that help provide a stable voltage supply and/or filter out noise within the integrated circuit device.

### BRIEF DESCRIPTION OF THE DRAWINGS

FIG. 1 is a schematic cross-sectional view of a conventional integrated circuit device.

FIG. 2A is a schematic block diagram of a transistor stack of an integrated circuit device according to some embodiments.

FIG. 2B is a schematic plan view of an integrated circuit device according to some embodiments.

FIG. 2C is a schematic cross-sectional view taken along line A-A′ of FIG. 2B.

FIG. 2D is a schematic cross-sectional view taken along line B-B′ of FIG. 2B.

FIG. 3A is a schematic block diagram of a MOSCAP of an integrated circuit device according to some embodiments.

FIG. 3B is a schematic plan view of an integrated circuit device according to some embodiments.

FIG. 3C is a schematic cross-sectional view taken along line B-B′ of FIG. 3B.

FIG. 3D is a schematic cross-sectional view taken along line C-C′ of FIG. 3B.

FIG. 3E is a schematic cross-sectional view taken along line D-D′ of FIG. 3B.

FIG. 3F is a schematic plan view of a frontside MOMCAP according to some embodiments.

FIG. 3G is a schematic plan view of an integrated circuit device including the frontside MOMCAP of FIG. 3F according to some embodiments.

FIG. 3H is a schematic plan view of a backside MOMCAP according to some embodiments.

FIG. 3I is a schematic plan view of an integrated circuit device including the backside MOMCAP of FIG. 3H according to some embodiments.

FIG. 3J is a schematic circuit diagram of the MOSCAP of FIGS. 3A, 3B, 3C, 3D, and 3E according to some embodiments.

FIG. 3K is a schematic circuit diagram of the integrated circuit device of FIGS. 3A, 3B, 3C, 3D, and 3E according to some embodiments.

FIG. 4 is a graph illustrating a C-V curve of the MOSCAP of FIGS. 3A, 3B, 3C, 3D, and 3E according to some embodiments.

FIG. 5A is a schematic plan view of a frontside MOMCAP according to some further embodiments.

FIG. 5B is a schematic plan view of a backside MOMCAP according to some further embodiments.

FIG. 6A is a schematic cross-sectional view taken along line C-C′ of FIG. 3B according to some further embodiments.

FIG. 6B is a schematic cross-sectional view taken along line D-D′ of FIG. 3B according to some further embodiments.

### DETAILED DESCRIPTION

Pursuant to example embodiments herein, integrated circuit devices are provided that include high-density capacitors. Example embodiments of the present application result, in part, from the realization that the existing architecture used to form three-dimensional (3D) stacked transistors, such as 3D stacked field-effect transistors (3DSFETs), in an integrated circuit device may be modified to provide one or more high-density capacitors in the integrated circuit device. These capacitors, for example, may function as decoupling capacitors that help provide a stable voltage supply and/or filter out noise within the integrated circuit device, although example embodiments are not limited thereto. By modifying the existing 3D stacked transistor architecture, the capacitors may be seamlessly implemented in the integrated circuit device, while operating in conjunction with the 3D stacked transistors.

Example embodiments will be described hereinafter in greater detail with reference to the attached figures.

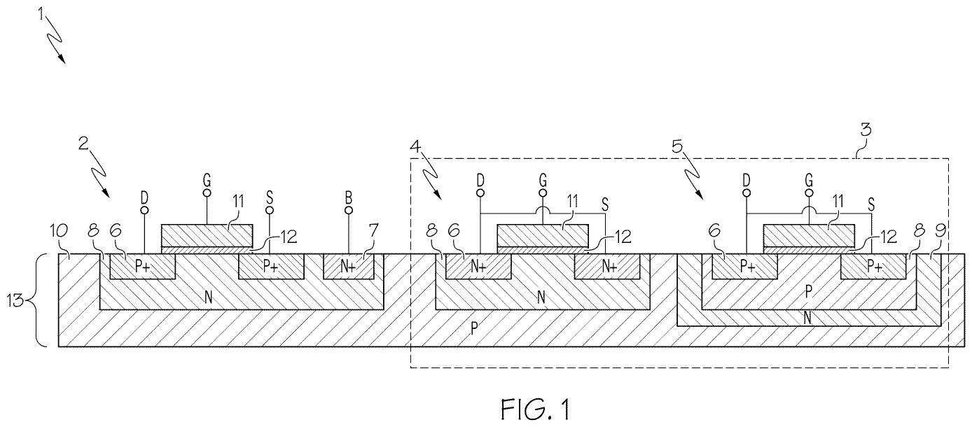

FIG. 1 is a schematic cross-sectional view of a conventional integrated circuit device. Referring to FIG. 1, the conventional integrated circuit device 1 may include a substrate 10, a planar transistor 2 on the substrate 10, and a metal-oxide-semiconductor capacitor (MOSCAP) 3 on the substrate 10. For example, as shown in FIG. 1, the planar transistor 2 may be a metal-oxide-semiconductor field-effect transistor (MOSFET), although embodiments of the present disclosure are not limited thereto.

The planar transistor 2 may include source/drain regions 6, a body region 7, and a well region 8. The planar transistor 2 may be a p-type transistor (e.g., a PMOS). It will be understood, however, that the conductivity types of the regions and/or layers may be reversed (i.e., p-type and n-type) in accordance with embodiments of the present disclosure. In other embodiments, the planar transistor 2 may be an n-type transistor (e.g., an NMOS), with the conductivity types of the source/drain regions 6, the body region 7, and the well region 8 reversed from that shown in FIG. 1. The source/drain regions 6, the body region 7, the well region 8, and the substrate 10 are part of a semiconductor layer structure 13 of the integrated circuit device 1.

The planar transistor 2 may further include a gate electrode 11 and a gate insulator 12. The gate electrode 11 and the gate insulator 12 are on an upper surface of the semiconductor layer structure 13. The gate insulator 12 may insulate (i.e., isolate) the gate electrode 11 from the semiconductor layer structure 13. The gate electrode 11 is electrically connected to a gate terminal G, the source/drain regions 6 are electrically connected to a drain terminal D and a source terminal S, respectively, and the body region 7 is electrically connected to a body terminal B. In some embodiments, the source terminal S may be electrically shorted to the body terminal B. Current flow between the source/drain regions 6 of the planar transistor 2 may be controlled based on a voltage applied to the gate terminal G.

As shown in FIG. 1, the MOSCAP 3 may include a first MOSCAP 4 and a second MOSCAP 5. As used herein, the MOSCAP 3 may also be referred to as a “MOS varactor.” The first MOSCAP 4 may be an n-type capacitor, and the second MOSCAP 5 may be a p-type capacitor.

The first MOSCAP 4 includes source/drain regions 6, a well region 8, a gate electrode 11, and a gate insulator 12. The source/drain regions 6 and the well region 8 are part of the semiconductor layer structure 13. The source/drain regions 6 are electrically connected to a drain terminal D and a source terminal S, respectively, and the gate electrode 11 is electrically connected to a gate terminal G. As shown in FIG. 1, the drain terminal D may be electrically shorted to the source terminal S. For example, the drain terminal D and the source terminal S may be electrically connected in common to an input signal.

The first MOSCAP 4 may operate as a voltage-controlled capacitor that relies on the capacitance between the gate electrode 11 and the underlying semiconductor layer structure 13. In more detail, the gate electrode 11 and the semiconductor layer structure 13 may form a capacitor, while the gate insulator 12 acts as a dielectric between the gate electrode 11 and the semiconductor layer structure 13. The gate electrode 11 and the semiconductor layer structure 13 can be thought of as the conductive plates of the capacitor, with the gate insulator 12 acting as the dielectric therebetween. In some embodiments, the gate electrode 11 includes a metal material, the gate insulator 12 includes an oxide insulating material (e.g., silicon oxide, although embodiments of the present disclosure are not limited thereto), and the semiconductor layer structure 13 includes a semiconductor material, hence the name metal-oxide-semiconductor capacitor (MOSCAP). The capacitance of the first MOSCAP 4 can be varied based on a voltage applied to the gate terminal G.

The second MOSCAP 5 includes source/drain regions 6, a well region 8, a deep well region 9, a gate electrode 11, and a gate insulator 12. The source/drain regions 6, the well region 8, and the deep well region 9 are part of the semiconductor layer structure 13. The source/drain regions 6 are electrically connected to a drain terminal D and a source terminal S, respectively, and the gate electrode 11 is electrically connected to a gate terminal G. As shown in FIG. 1, the drain terminal D may be electrically shorted to the source terminal S. For example, the drain terminal D and the source terminal S may be electrically connected in common to an input signal. The second MOSCAP 5 may operate as a voltage-controlled capacitor that relies on the capacitance between the gate electrode 11 and the underlying semiconductor layer structure 13. The capacitance of the second MOSCAP 5 can be varied based on a voltage applied to the gate terminal G.

Still referring to FIG. 1, the capacitance value of the first MOSCAP 4 and the second MOSCAP 5 may vary depending on whether the first MOSCAP 4 and the second MOSCAP 5 operate in an accumulation region, a depletion region, or an inversion region. The first MOSCAP 4 and the second MOSCAP 5 may each operate in the accumulation region, the depletion region, or the inversion region based on a voltage applied to the respective gate terminals G of the first MOSCAP 4 and the second MOSCAP 5. The well regions 8 and the deep well region 9 of the semiconductor layer structure 13 may allow for the first MOSCAP 4 and the second MOSCAP 5 to be configured such that they have (i.e., they exhibit) a maximum capacitance value when they operate in the accumulation region.

As described above, the first MOSCAP 4 and the second MOSCAP 5 may each operate as a voltage-controlled capacitor where a capacitance value thereof can be varied based on a voltage applied to the respective gate terminals G. The MOSCAP 3 including the first MOSCAP 4 and the second MOSCAP 5 may thus operate as a MOS varactor.

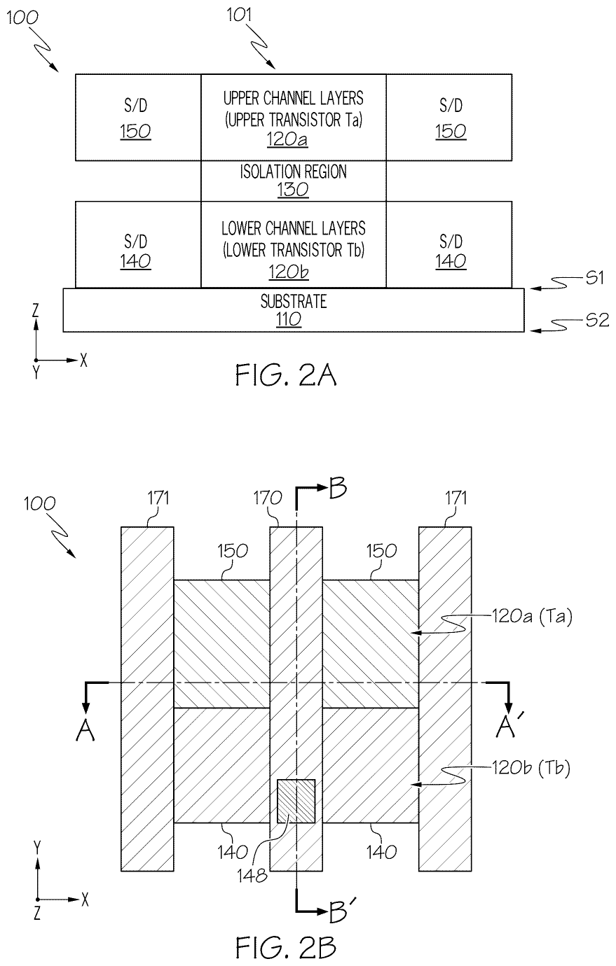

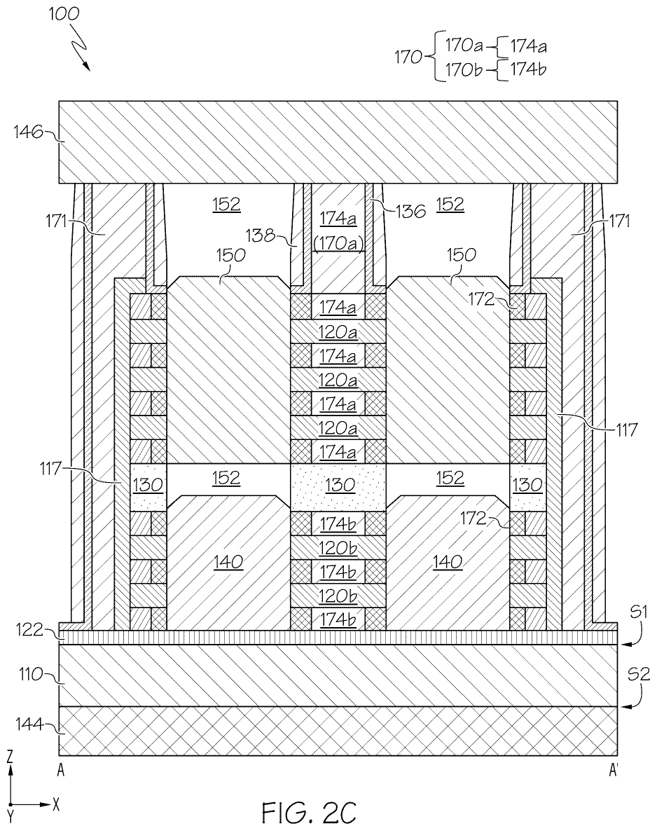

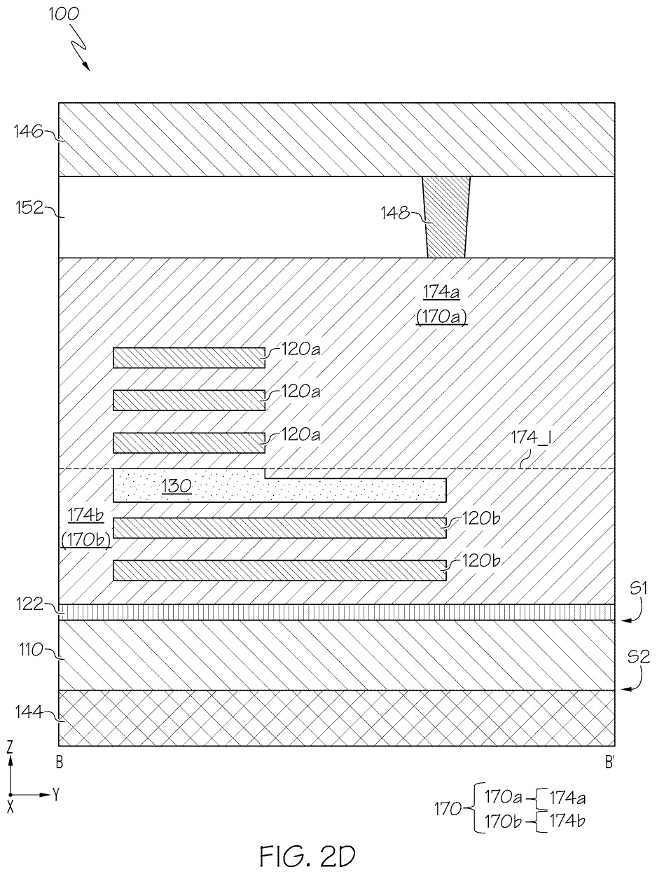

FIG. 2A is a schematic block diagram of a transistor stack of an integrated circuit device according to some embodiments.

Referring to FIG. 2A, an integrated circuit device 100 includes a substrate 110 and a transistor stack 101 on a first surface S1 (i.e., the frontside) of the substrate 110. The substrate 110 may extend in a first direction X (also referred to as a first horizontal direction) and a second direction Y (also referred to as a second horizontal direction). The first direction X and the second direction Y may be parallel to a surface (e.g., the first surface S1 and/or a second surface S2) of the substrate 110. For example, the first direction X may intersect the second direction Y. In some embodiments, the first direction X may be perpendicular to the second direction Y.

The first surface S1 of the substrate 110 is opposite the second surface S2 (i.e., the backside) of the substrate 110 in a third direction Z (also referred to as a vertical direction). For example, the third direction Z may intersect the first direction X and the second direction Y. In some embodiments, the third direction Z may be perpendicular to the first direction X and/or the second direction Y. The third direction Z may be perpendicular to a surface (e.g., the first surface S1 and/or the second surface S2) of the substrate 110. As used herein, the first surface S1 may also be referred to as an “upper surface” of the substrate 110, and the second surface S2 may also be referred to as a “lower surface” of the substrate 110.

In some embodiments, the substrate 110 may include or may be formed of insulating material(s), for example, silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. A thickness of the substrate 110 in the third direction Z may be, for example, in a range of (about) 50 nanometers (nm) to 100 nm, but is not limited thereto.

The transistor stack 101 includes a lower transistor Tb having a stack of lower semiconductor channel layers 120b, and an upper transistor Ta having a stack of upper semiconductor channel layers 120a. The channel layers 120a, 120b may comprise, for example, semiconductor material(s) (e.g., Si, Ge, SiGe, GaP, GaAs, SiC, SiGeC and/or InP). In some embodiments, the channel layers 120a, 120b may be nanosheets that may have a thickness, for example, in a range of (about) 1 nm to 100 nm in the third direction Z, or may be nanowires that may have a circular cross-section with a diameter, for example, in a range of (about) 1 nm to 100 nm.

The lower transistor Tb is between, in the third direction Z, the upper transistor Ta and the substrate 110. For example, the upper transistor Ta may overlap the lower transistor Tb in the third direction Z. As used herein, “an element A overlaps an element B in a direction” (or similar language) means that there is at least one straight line that extends in the direction and intersects both the elements A and B. The transistor stack 101 may also include an isolation region 130, such as a middle dielectric isolation (MDI) region. The isolation region 130 may, in some embodiments, serve as a spacer between the upper and lower transistors Ta, Tb. The isolation region 130 may thus also be referred to herein as a “spacer.”

The lower channel layers 120b of the lower transistor Tb are between, in the first direction X, a pair of lower source/drain (S/D) regions 140 that are electrically connected to the lower channel layers 120b. Likewise, the upper channel layers 120a of the upper transistor Ta are between, in the first direction X, a pair of upper source/drain regions 150 that are electrically connected to the upper channel layers 120a. The lower source/drain regions 140 may be between, in the third direction Z, the upper source/drain regions 150 and the substrate 110.

The lower source/drain regions 140 and the upper source/drain regions 150 may each include a semiconductor layer (e.g., a silicon (Si) layer, a silicon carbide (SiC) layer, and/or a silicon germanium (SiGe) layer) and may additionally include dopants in the semiconductor layer. For example, each of the lower and upper source/drain regions 140, 150 may include an epitaxial semiconductor layer having dopants (i.e., impurities) therein. In some embodiments, the upper source/drain regions 150 may include a different semiconductor material from that of the lower source/drain regions 140. As an example, the upper source/drain regions 150 may include silicon germanium, and the lower source/drain regions 140 may include silicon carbide, or vice versa. In other embodiments, the upper source/drain regions 150 may include the same semiconductor material as the lower source/drain regions 140.

In some embodiments, the lower source/drain regions 140 have a first conductivity type and the upper source/drain regions 150 have a second conductivity type. As used herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity. For example, the lower source/drain regions 140 may include n-type impurities (e.g., phosphorus (P), arsenic (As), antimony (Sb), etc.) and the upper source/drain regions 150 may include p-type impurities (e.g., boron (B), gallium (Ga), indium (In), etc.), or vice versa.

The lower transistor Tb and the upper transistor Ta may have complementary conductivity types (e.g., to provide a complementary metal-oxide-semiconductor (CMOS) device). For example, the lower transistor Tb may have a first conductivity type, while the upper transistor Ta may have a second conductivity type. Also, while illustrated with reference to the lower transistor Tb and the upper transistor Ta, it will be understood that the transistor stack 101 is not limited to a two-transistor arrangement, and may include additional transistors that are vertically stacked on the substrate 110, according to some embodiments.

For simplicity of illustration, only one transistor stack 101 is shown in FIG. 2A. It will be understood, however, that the integrated circuit device 100 may include two, three, four, or more transistor stacks 101, according to some embodiments.

FIG. 2B is a schematic plan view of an integrated circuit device according to some embodiments. For simplicity of illustration, FIG. 2B only shows some elements of the integrated circuit device 100. As shown in FIG. 2B, the integrated circuit device 100 includes one or more gate structures 170 on the upper channel layers 120a of the upper transistor Ta and the lower channel layers 120b of the lower transistor Tb. An upper gate contact 148 may be electrically connected to the gate structure 170. In some embodiments, the integrated circuit device 100 also includes dummy gate structures 171. A line A-A′ extends along a channel width of the upper channel layers 120a of the upper transistor Ta in the first direction X. A line B-B′ passes lengthwise (i.e., longitudinally) through a gate structure 170 in the second direction Y.

FIG. 2C is a schematic cross-sectional view taken along line A-A′ of FIG. 2B. Referring to FIGS. 2B and 2C, the gate structure 170 may include an upper gate structure 170a and a lower gate structure 170b. The pair of upper source/drain regions 150, the upper channel layers 120a, and the upper gate structure 170a form, in part, the upper transistor Ta. The pair of lower source/drain regions 140, the lower channel layers 120b, and the lower gate structure 170b form, in part, the lower transistor Tb. The lower transistor Tb and the upper transistor Ta comprise the transistor stack 101 (see FIG. 2A) of the integrated circuit device 100. As used herein, the upper channel layers 120a may also be referred to as an “upper channel region”, and the lower channel layers 120b may also be referred to as a “lower channel region.”

The pair of upper source/drain regions 150 may be spaced apart from each other (e.g., in the first direction X), with the upper gate structure 170a therebetween. The pair of lower source/drain regions 140 may be spaced apart from each other (e.g., in the first direction X), with the lower gate structure 170b therebetween. The upper channel layers 120a may be between (e.g., in the first direction X) the pair of upper source/drain regions 150. The source/drain regions 150 are electrically connected to the upper channel layers 120a. As shown in FIG. 2C, the upper channel layers 120a may be spaced apart from each other in the third direction Z, with the upper gate structure 170a therebetween. Although FIG. 2C illustrates three upper channel layers 120a, the present disclosure is not limited thereto. In other embodiments, the integrated circuit device 100 may include more than three upper channel layers 120a or less than three upper channel layers 120a. The lower channel layers 120b may be between (e.g., in the first direction X) the pair of lower source/drain regions 140. The source/drain regions 140 are electrically connected to the lower channel layers 120b. As shown in FIG. 2C, the lower channel layers 120b may be spaced apart from each other in the third direction Z, with the lower gate structure 170b therebetween. Although FIG. 2C illustrates two lower channel layers 120b, the present disclosure is not limited thereto. In other embodiments, the integrated circuit device 100 may include more than two lower channel layers 120b or only one lower channel layer 120b.

The upper gate structure 170a may be on the upper channel layers 120a of the upper transistor Ta, and the lower gate structure 170b may be on the lower channel layers 120b of the lower transistor Tb. The upper gate structure 170a includes an upper conductive gate 174a. The upper conductive gate 174a may be between (e.g., in the third direction Z) the upper channel layers 120a, and may be spaced apart from the upper source/drain regions 150 in the first direction X by inner spacers 172. The inner spacers 172 may be on sidewalls of the upper conductive gate 174a and between, in the third direction Z, the upper channel layers 120a. The inner spacers 172 may include insulating material(s) (e.g., silicon oxide, silicon oxynitride, silicon nitride, silicon carbonitride and/or a low-k material).

The lower gate structure 170b may include a lower conductive gate 174b that is between (e.g., in the third direction Z) the lower channel layers 120b. The lower conductive gate 174b may be spaced apart from the lower source/drain regions 140 in the first direction X by inner spacers 172, which may be on sidewalls of the lower conductive gate 174b and between, in the third direction Z, the lower channel layers 120b. In some embodiments, the inner spacers 172 may contact the lower source/drain regions 140, the upper source/drain regions 150, sidewalls of the lower conductive gate 174b, and sidewalls of the upper conductive gate 174a. Sidewalls of the lower channel layers 120b may contact the lower source/drain regions 140, and sidewalls of the upper channel layers 120a may contact the upper source/drain regions 150.

The upper conductive gate 174a and the lower conductive gate 174b may each include a metal material (e.g., tungsten (W), aluminum (Al), copper (Cu), molybdenum (Mo), cobalt (Co), and/or ruthenium (Ru)) and/or a semiconductor material. In some embodiments, the upper conductive gate 174a and the lower conductive gate 174b may each include a metal layer and work function layer(s) (e.g., a TiN layer, a TaN layer, a TiAl layer, a TiC layer, a TiAlC layer, a TiAlN layer and/or a WN layer). For example, the work function layer(s) may be provided between the metal layer and a gate insulation layer (not shown). In some embodiments, the work function layer(s) may separate the metal layer from the gate insulation layer.

In some embodiments, the upper conductive gate 174a and the lower conductive gate 174b may comprise different metals, respectively. In other embodiments, the upper conductive gate 174a and the lower conductive gate 174b may comprise the same metal material.

For simplicity of illustration, a gate insulation layer is omitted from view in FIG. 2C. It will be understood, however, that each gate structure 170 may include a gate insulation layer that extends between a channel layer 120a, 120b and a conductive gate 174a, 174b. The gate insulation layer may surround the conductive gate 174a, 174b and may separate (i.e., insulate) the conductive gate 174a, 174b from the channel layers 120a, 120b. In some embodiments, the gate insulation layer may be thinner than the isolation region 130 (e.g., in the third direction Z). The gate insulation layer may include a single layer or multiple layers (e.g., a silicon oxide layer and/or a high-k material layer). For example, the high-k material layer may include Al₂O₃, HfO₂, ZrO₂, HfZrO₄, TiO₂, Sc₂O₃ Y₂O₃, La₂O₃, Lu₂O₃, Nb₂O₅ and/or Ta₂O₅. It will be understood that “an element A surrounds an element B” (or similar language) as used herein means that the element A is at least partially around the element B but does not necessarily mean that the element A completely encloses the element B.

The isolation region 130 may be a spacer that separates the lower channel layers 120b of the lower transistor Tb from the upper channel layers 120a of the upper transistor Ta. The isolation region 130 may be between the upper gate structure 170a and the lower gate structure 170b (e.g., in the third direction Z). The isolation region 130 may comprise, for example, one or more isolation layers including insulating material(s) (e.g., silicon oxide, silicon oxynitride, silicon nitride, silicon carbonitride, silicon boron carbonitride (SiBCN), and/or a low-k material). Although FIG. 2C illustrates the isolation region 130 as a single layer, in some embodiments, the isolation region 130 may include multiple layers.

In some embodiments, an interlayer 122 may be provided on the first surface S1 of the substrate 110. For example, the interlayer 122 may extend between the substrate 110 and the lower transistor Tb. The interlayer 122 may contact the first surface S1 of the substrate 110 and the lower transistor Tb (e.g., the lower source/drain regions 140 and the lower gate structure 170b). For example, the interlayer 122 may include insulating material(s) (e.g., silicon oxide, silicon oxynitride, silicon nitride, silicon carbonitride and/or a low-k material). In other embodiments, the interlayer 122 may be omitted.

Upper spacers 138 may be on opposing sidewalls of an upper portion of the upper gate structure 170a. An insulating liner 136 may be between the upper spacers 138 and the upper portion of the upper gate structure 170a. The upper spacers 138 and the insulating liner 136 may comprise, for example, insulating material(s) (e.g., silicon oxide, silicon oxynitride, silicon nitride, silicon carbonitride, silicon boron carbonitride (SiBCN), and/or a low-k material).

The integrated circuit device 100 may further include a first insulating layer 152 between, in the third direction Z, the lower and upper source/drain regions 140, 150. The first insulating layer 152 may separate the lower source/drain regions 140 from the upper source/drain regions 150. The first insulating layer 152 may also be on an upper surface of each of the upper source/drain regions 150. For example, the first insulating layer 152 may surround the lower and upper source/drain regions 140, 150. The first insulating layer 152 may comprise, for example, insulating material(s) (e.g., silicon oxide, silicon oxynitride, silicon nitride, silicon carbonitride, silicon boron carbonitride (SiBCN), and/or a low-k material). Although the first insulating layer 152 is illustrated as a single layer, in some embodiments, the first insulating layer 152 may include multiple layers.

The dummy gate structures 171 may be gate structures that do not function electrically (e.g., non-active gate structures) and may be formed to replicate a physical structure of the gate structure 170. In some embodiments, dummy gate spacers 117 may be on sidewalls of the dummy gate structures 171, respectively. The dummy gate spacers 117 may comprise, for example, insulating material(s) (e.g., silicon oxide, silicon oxynitride, silicon nitride, silicon carbonitride, silicon boron carbonitride (SiBCN), and/or a low-k material). In other embodiments, the dummy gate spacers 117 and the dummy gate structures 171 may be omitted and replaced with gate structures 170.

The integrated circuit device 100 further includes an upper structure 146 on the first insulating layer 152. The upper structure 146 may include elements formed by the middle-of-line (MOL) portion and/or the back-end-of-line (BEOL) portion of device fabrication. As used herein, the upper structure 146 may also be referred to as a “BEOL structure.” The upper structure 146 may include conductive elements (e.g., wire(s) and/or via plug(s)) and insulating elements (e.g., interlayer(s) and/or spacer(s)). For example, the upper structure 146 may include an interlayer insulating layer, conductive wires (e.g., metal wires) that are provided in the interlayer insulating layer and are stacked in the third direction Z, and conductive via plugs (e.g., metal via plugs), each of which may electrically connect two conductive wires that are spaced apart from each other in the third direction Z. Although not shown in the cross-sectional view of FIG. 2C, the conductive elements of the upper structure 146 may be electrically connected to, for example, one or more of the upper source/drain regions 150, one or more of the lower source/drain regions 140, and/or the gate structure 170.

The integrated circuit device 100 may further include a backside power distribution network (BSPDN) structure 144 on the second surface S2 (i.e., the backside) of the substrate 110. Backside contact structures (not shown) may electrically connect the BSPDN structure 144 to one or more of the lower source/drain regions 140. The BSPDN structure 144 may include a backside insulator and one or more backside power rails provided in the backside insulator. The backside power rail may be electrically connected to a power source with a predetermined voltage (e.g., a drain voltage (Vdd) and/or a source voltage (Vss)). For example, the BSPDN structure 144 may include a power delivery network. The power delivery network may include a wiring network, which is used to deliver power (e.g., gate voltages and/or source/drain voltages) to the backside power rail.

As used herein, the backside power rail may refer to one or more conductive elements included in the BSPDN structure 144. For example, the backside power rail may include a power rail, a conductive via plug, and/or a conductive wire included in the BSPDN structure 144. That is, the BSPDN structure 144 may include one or more conductive layers (e.g., metal layers) stacked in the third direction Z that provide backside power delivery to, for example, the lower transistor Tb. The conductive layers may respectively be included in insulating layers, and conductive via plugs (e.g., metal via plugs) may electrically connect the conductive layers to each other in the third direction Z. The conductive layers may include one or more conductive wires (e.g., metal wires).

In some embodiments, an intervening structure (not shown) may be provided between the substrate 110 and the BSPDN structure 144 and may separate the substrate 110 from the BSPDN structure 144. The BSPDN structure 144 may increase a power delivery efficiency in the integrated circuit device 100, reduce an area used for power delivery in the integrated circuit device 100, and/or improve a voltage drop (i.e., IR drop) in the integrated circuit device 100.

In some embodiments, the upper and lower transistors Ta, Tb may be different types of MOSFETs. The integrated circuit device 100 may thus include a stacked FET device. For example, the upper and lower transistors Ta, Tb may be PMOS and NMOS transistors, respectively, or vice versa. In some embodiments, the upper and lower transistors Ta, Tb may each be a three-dimensional (3D) field-effect transistor (FET) such as a multi-bridge channel FET (MBCFET) or a gate-all-around FET (GAAFET), although embodiments of the present disclosure are not limited thereto. In some embodiments, the upper and lower transistors Ta, Tb may be formed as a CMOS structure. The upper and lower transistors Ta, Tb may be stacked in the third direction Z on the substrate 110.

FIG. 2D is a schematic cross-sectional view taken along line B-B′ of FIG. 2B. Referring to FIGS. 2B and 2D, the lower gate structure 170b may surround the lower channel layers 120b. For example, the lower gate structure 170b (e.g., the lower conductive gate 174b) may be on an upper surface, a lower surface, and opposing side surfaces of each lower channel layer 120b. For simplicity of illustration, the gate insulation layer of the lower gate structure 170b is omitted from view in FIG. 2D. It will be understood, however, that the gate insulation layer may be provided between each lower channel layer 120b and the lower conductive gate 174b, and may separate the lower conductive gate 174b from the lower channel layers 120b.

The upper gate structure 170a may surround the upper channel layers 120a. For example, the upper gate structure 170a (e.g., the upper conductive gate 174a) may be on an upper surface, a lower surface, and opposing side surfaces of each upper channel layer 120a. For simplicity of illustration, the gate insulation layer of the upper gate structure 170a is omitted from view in FIG. 2D. It will be understood, however, that the gate insulation layer may be provided between each upper channel layer 120a and the upper conductive gate 174a, and may separate the upper conductive gate 174a from the upper channel layers 120a.

An upper gate contact 148 extends into the first insulating layer 152 and may electrically connect the lower gate structure 170b (e.g., the lower conductive gate 174b) and the upper gate structure 170a (e.g., the upper conductive gate 174a) to the upper structure 146. The upper gate contact 148 may include a metal layer or material including, for example, W, Al, Cu, Mo, Co and/or Ru.

The isolation region 130 separates and electrically isolates the lower channel layers 120b from the upper channel layers 120a. In some embodiments, the lower channel layers 120b (e.g., lower nanosheets) may be wider, in the second direction Y, than the upper channel layers 120a (e.g., upper nanosheets). For example, in some embodiments, the lower channel layers 120b may be more than twice as wide as the upper channel layers 120a. In some embodiments, the isolation region 130 may have the same width as the lower channel layers 120b in the second direction Y.

As shown in FIG. 2D, the upper gate structure 170a (e.g., the upper conductive gate 174a) and the lower gate structure 170b (e.g., the lower conductive gate 174b) are in electrical contact with each other (i.e., are electrically connected to each other) and share an interface 174_I (shown by a dashed line in FIG. 2D). In some embodiments, a common gate voltage (i.e., a common gate signal) may be applied to both the upper conductive gate 174a and the lower conductive gate 174b (e.g., via the upper gate contact 148).

Referring back to FIG. 1, the integrated circuit device 1 includes the planar transistor 2 and the MOSCAP 3, as described above. For example, the MOSCAP 3 may operate in conjunction with the planar transistor 2 and may function as a decoupling capacitor. The MOSCAP 3 may thus improve the performance and reliability of the integrated circuit device 1.

Similar to the integrated circuit device 1, it may be advantageous to provide a MOSCAP to operate in conjunction with the upper and lower transistors Ta, Tb of the transistor stack 101 in FIGS. 2A-D. For example, a MOSCAP may help provide a stable voltage supply and/or filter out noise within the integrated circuit device 100. However, at least two challenges exist in implementing a MOSCAP in the integrated circuit device 100. First, the upper and lower transistors Ta, Tb of the integrated circuit device 100 do not include well regions, and thus the MOSCAP 3 (including the first and second MOSCAPs 4, 5) of the conventional integrated circuit device 1 cannot be implemented in the integrated circuit device 100. Second, the upper gate structure 170a (e.g., the upper conductive gate 174a) of the upper transistor Ta and the lower gate structure 170b (e.g., the lower conductive gate 174b) of the lower transistor Tb are electrically connected to each other, and thus a gate voltage (i.e., a gate signal) cannot be individually applied to the upper and lower transistors Ta, Tb. As a result, if the upper and lower transistors Ta, Tb were reconfigured to operate as capacitors, only the upper transistor Ta or the lower transistor Tb would exhibit a high capacitance value responsive to the gate voltage, since the upper and lower transistors Ta, Tb have opposite conductivity types and will thus operate in different regions from each other among an accumulation region, a depletion region, and an inversion region responsive to the common gate voltage. While the upper and lower transistors Ta, Tb may be modified to have a same conductivity type, doing so presents a tradeoff, as the integrated circuit device 100 would no longer be suitable for applications where the CMOS structure of the upper and lower transistors Ta, Tb is utilized.

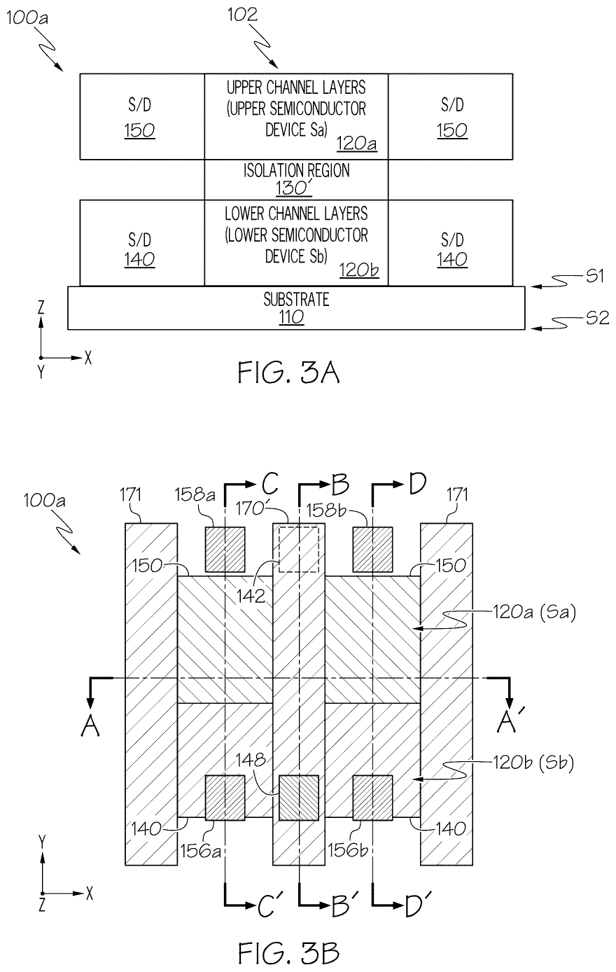

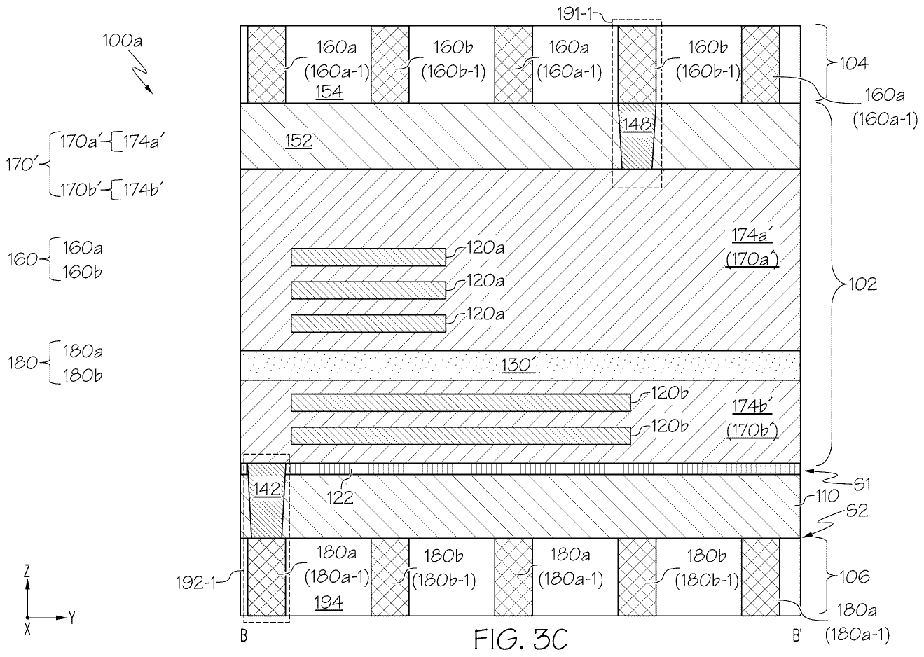

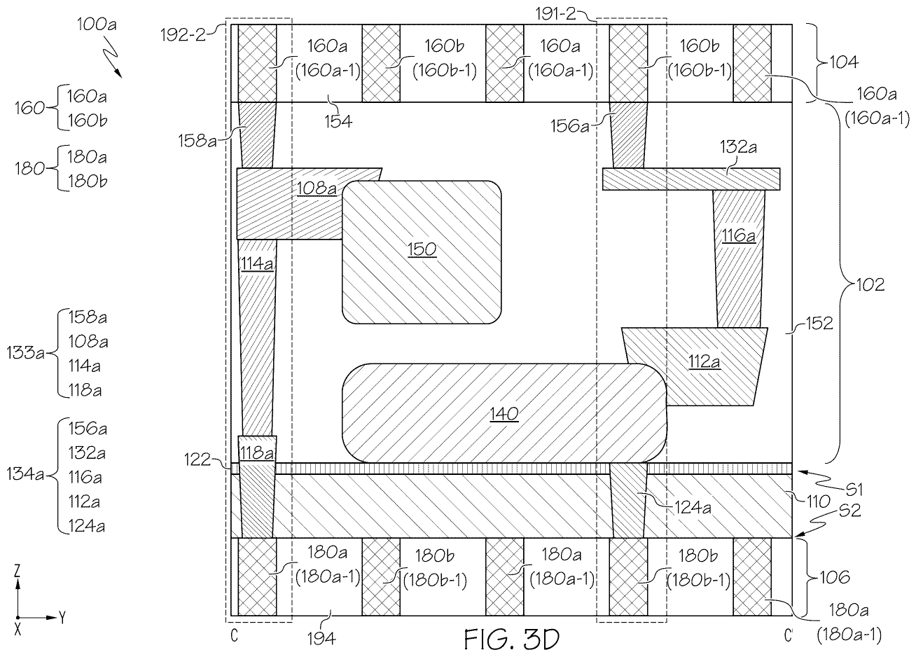

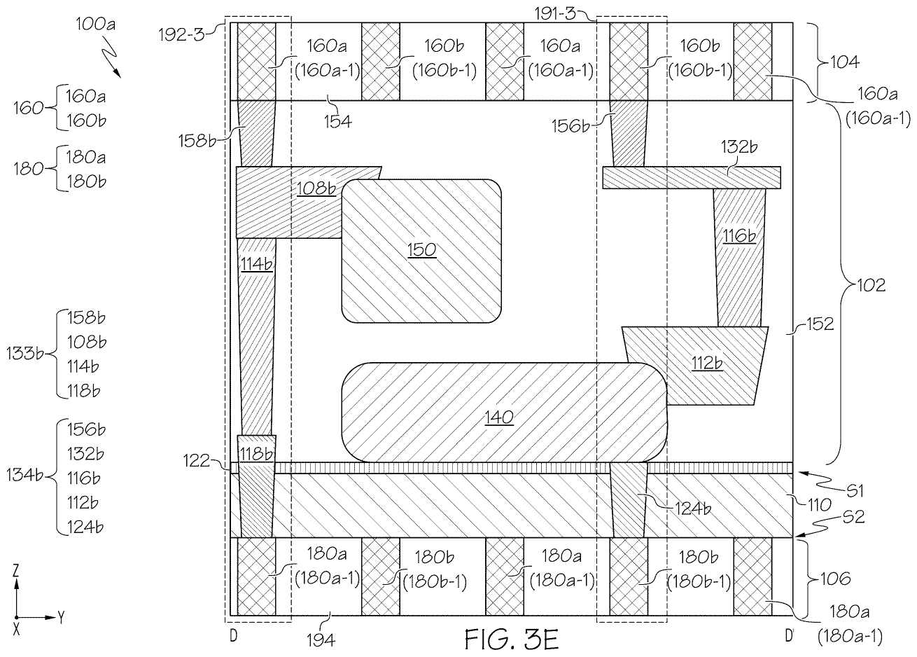

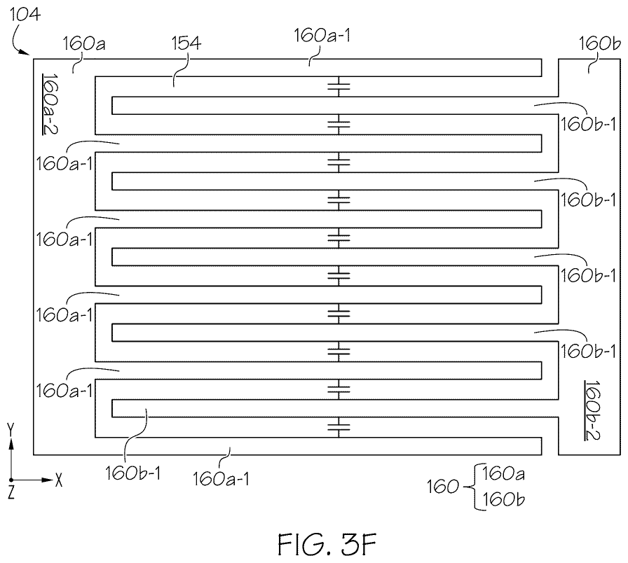

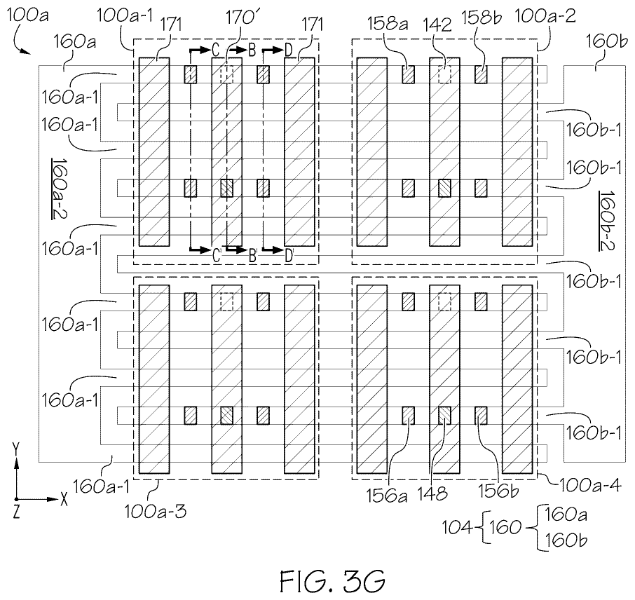

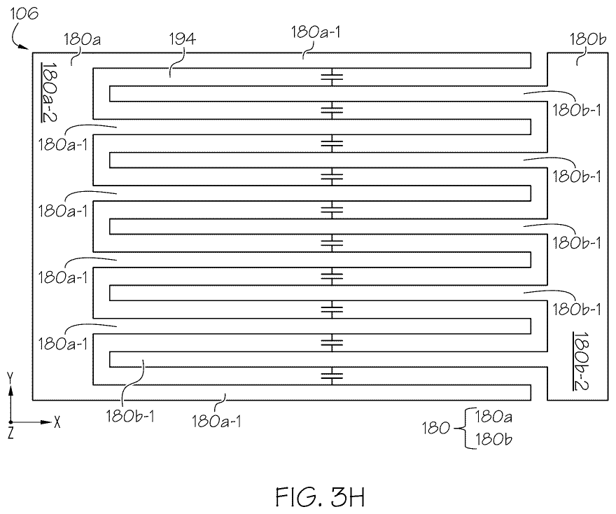

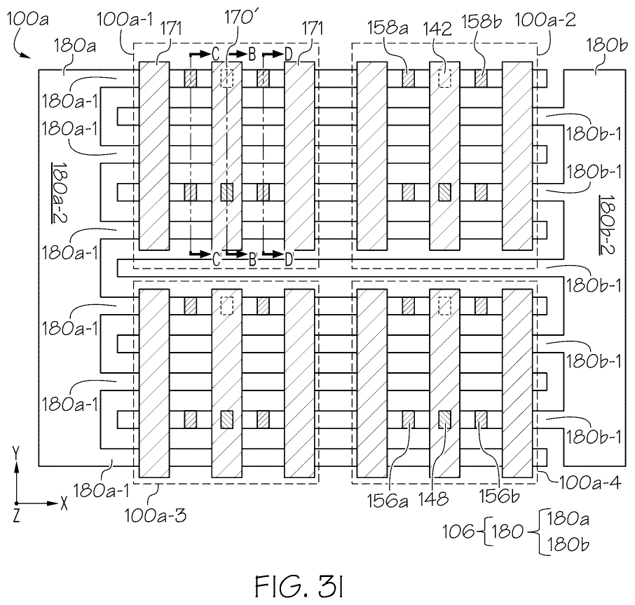

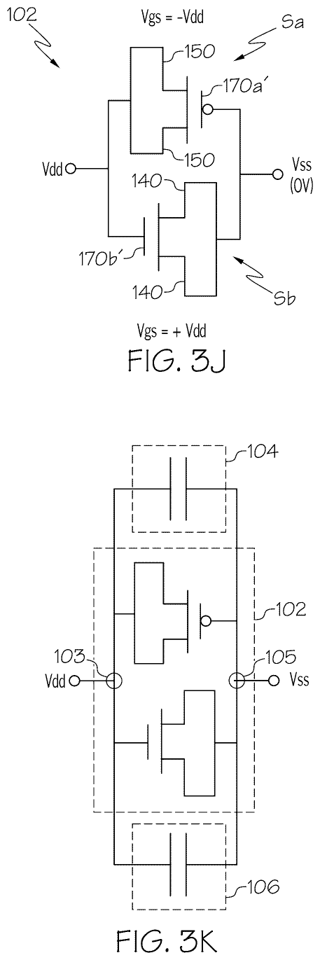

FIG. 3A is a schematic block diagram of a MOSCAP of an integrated circuit device according to some embodiments. Like reference numerals refer to like elements. For simplicity of description, repeated descriptions of like elements described above may be omitted.

Referring to FIG. 3A, the integrated circuit device 100a includes the substrate 110 and a MOSCAP 102 on the first surface S1 (i.e., the frontside) of the substrate 110. The MOSCAP 102 includes a lower semiconductor device Sb having a stack of lower semiconductor channel layers 120b, and an upper semiconductor device Sa having a stack of upper semiconductor channel layers 120a. The lower semiconductor device Sb is between, in the third direction Z, the upper semiconductor device Sa and the substrate 110. For example, the upper semiconductor device Sa may overlap the lower semiconductor device Sb in the third direction Z. The lower channel layers 120b are between the pair of lower source/drain regions 140 (e.g., in the first direction X). The upper channel layers 120a are between the pair of upper source/drain regions 150 (e.g., in the first direction X).

The MOSCAP 102 may also include an isolation region 130′, such as a middle dielectric isolation (MDI) region. The isolation region 130′ may, in some embodiments, serve as a spacer between the upper and lower semiconductor devices Sa, Sb. The isolation region 130′ may thus also be referred to herein as a “spacer.” The lower semiconductor device Sb and the upper semiconductor device Sa may have opposite conductivity types. For example, the lower semiconductor device Sb may have a first conductivity type, while the upper semiconductor device Sa may have a second conductivity type.

For simplicity of illustration, only one MOSCAP 102 is shown in FIG. 3A. It will be understood, however, that the integrated circuit device 100a may include two, three, four, or more MOSCAPs 102, according to some embodiments. In some embodiments, the integrated circuit device 100a includes at least one MOSCAP 102 and at least one transistor stack 101 (see FIGS. 2A-D). For example, the transistor stack 101 and the MOSCAP 102 may both be formed during the front-end-of-line (FEOL) portion of device fabrication.

FIG. 3B is a schematic plan view of an integrated circuit device according to some embodiments. For simplicity of illustration, FIG. 3B only shows some elements of the integrated circuit device 100a. As shown in FIG. 3B, the integrated circuit device 100a includes one or more gate structures 170′ on the upper channel layers 120a of the upper semiconductor device Sa and the lower channel layers 120b of the lower semiconductor device Sb. The upper gate contact 148 and a lower gate contact 142 (shown by a dotted line box in FIG. 3B) may be electrically connected to the gate structure 170'. First and second upper conductive plugs 158a, 158b are electrically connected to the pair of upper source/drain regions 150, respectively. Third and fourth upper conductive plugs 156a, 156b are electrically connected to the pair of lower source/drain regions 140, respectively. In some embodiments, the integrated circuit device 100a also includes the dummy gate structures 171. A line A-A′ extends along a channel width of the upper channel layers 120a of the upper semiconductor device Sa in the first direction X. A line B-B′ passes lengthwise (i.e., longitudinally) through the gate structure 170′ in the second direction Y. A line C-C′ passes through a first one of the pair of upper source/drain regions 150 and a first one of the pair of lower source/drain regions 140 in the second direction Y. A line D-D′ passes through a second one of the pair of upper source/drain regions 150 and a second one of the pair of lower source/drain regions 140 in the second direction Y.

A cross-sectional view of the integrated circuit device 100a taken along line A-A′ of FIG. 3B is substantially the same as that shown in FIG. 2C, except that the upper structure 146 of FIG. 2C may be reconfigured as a frontside metal-oxide-metal capacitor (MOMCAP) 104, and the BSPDN structure 144 of FIG. 2C may be reconfigured as a backside MOMCAP 106. It will be understood that the description of the integrated circuit device 100 with reference to FIG. 2C is generally applicable to the integrated circuit device 100a (unless the context clearly indicates otherwise), except for the description of the upper structure 146 and the BSPDN structure 144 of FIG. 2C. As such, for simplicity of illustration, a cross-sectional view of the integrated circuit device 100a taken along line A-A′ of FIG. 3B is omitted.

FIG. 3C is a schematic cross-sectional view taken along line B-B′ of FIG. 3B. Referring to FIGS. 3B and 3C, the gate structure 170′ may include an upper gate structure 170a′ and a lower gate structure 170b′. The pair of upper source/drain regions 150, the upper channel layers 120a, and the upper gate structure 170a′ may form, in part, the upper semiconductor device Sa. The pair of lower source/drain regions 140, the lower channel layers 120b, and the lower gate structure 170b′ may form, in part, the lower semiconductor device Sb. The upper semiconductor device Sa and the lower semiconductor device Sb comprise the MOSCAP 102 of the integrated circuit device 100a.

The upper gate structure 170a′ may be on the upper channel layers 120a of the upper semiconductor device Sa, and the lower gate structure 170b′ may be on the lower channel layers 120b of the lower semiconductor device Sb. The upper gate structure 170a′ includes an upper conductive gate 174a′. The upper conductive gate 174a′ may be between (e.g., in the third direction Z) the upper channel layers 120a. The upper channel layers 120a may be stacked and spaced apart from each other in the third direction Z. The lower gate structure 170b′ includes a lower conductive gate 174b′. The lower conductive gate 174b′ may be between (e.g., in the third direction Z) the lower channel layers 120b. The lower channel layers 120b may be stacked and spaced apart from each other in the third direction Z.

The upper conductive gate 174a′ and the lower conductive gate 174b′ may each include a metal material (e.g., tungsten (W), aluminum (Al), copper (Cu), molybdenum (Mo), cobalt (Co), and/or ruthenium (Ru)) and/or a semiconductor material. In some embodiments, the upper conductive gate 174a′ and the lower conductive gate 174b′ may each include a metal layer and work function layer(s) (e.g., a TiN layer, a TaN layer, a TiAl layer, a TiC layer, a TiAlC layer, a TiAlN layer and/or a WN layer). For example, the work function layer(s) may be provided between the metal layer and a gate insulation layer (not shown). In some embodiments, the work function layer(s) may separate the metal layer from the gate insulation layer. In some embodiments, the upper conductive gate 174a′ and the lower conductive gate 174b′ may comprise different metals, respectively. In other embodiments, the upper conductive gate 174a′ and the lower conductive gate 174b′ may comprise the same metal material.

The lower gate structure 170b′ may surround the lower channel layers 120b. For example, the lower gate structure 170b′ (e.g., the lower conductive gate 174b′) may be on an upper surface, a lower surface, and opposing side surfaces of each lower channel layer 120b. For simplicity of illustration, the gate insulation layer of the lower gate structure 170b′ is omitted from view in FIG. 3C. It will be understood, however, that the gate insulation layer may be provided between each lower channel layer 120b and the lower conductive gate 174b′, and may separate the lower conductive gate 174b′ from the lower channel layers 120b. In some embodiments, the gate insulation layer may be thinner than the isolation region 130′ (e.g., in the third direction Z). The lower gate structure 170b′ is between the pair of lower source/drain regions 140 (e.g., in the first direction X).

The upper gate structure 170a′ may surround the upper channel layers 120a. For example, the upper gate structure 170a′ (e.g., the upper conductive gate 174a′) may be on an upper surface, a lower surface, and opposing side surfaces of each upper channel layer 120a. For simplicity of illustration, the gate insulation layer of the upper gate structure 170a′ is omitted from view in FIG. 3C. It will be understood, however, that the gate insulation layer may be provided between each upper channel layer 120a and the upper conductive gate 174a′, and may separate the upper conductive gate 174a′ from the upper channel layers 120a. The upper gate structure 170a′ is between the pair of upper source/drain regions 150 (e.g., in the first direction X).

The isolation region 130′ may be a spacer that separates the lower channel layers 120b of the lower semiconductor device Sb from the upper channel layers 120a of the upper semiconductor device Sa. The isolation region 130′ may be between the upper gate structure 170a′ and the lower gate structure 170b′ (e.g., in the third direction Z). The isolation region 130′ may comprise, for example, one or more isolation layers including insulating material(s) (e.g., silicon oxide, silicon oxynitride, silicon nitride, silicon carbonitride, silicon boron carbonitride, and/or a low-k material). Although FIG. 3C illustrates the isolation region 130′ as a single layer, in some embodiments, the isolation region 130′ may include multiple layers.

As shown in FIG. 3C, the isolation region 130′ separates (e.g., electrically separates) the lower gate structure 170b′ from the upper gate structure 170a′. For example, the isolation region 130′ may insulate (i.e., electrically isolate) the lower conductive gate 174b′ from the upper conductive gate 174a′. Unlike the integrated circuit device 100 described above with reference to FIG. 2D, the upper gate structure 170a′ (e.g., the upper conductive gate 174a′) and the lower gate structure 170b′ (e.g., the lower conductive gate 174b′) are not in electrical contact with each other. In some embodiments, the lower gate structure 170b′ (e.g., the lower conductive gate 174b′) may be configured to receive a first voltage (i.e., a first gate signal), and the upper gate structure 170a′ (e.g., the upper conductive gate 174a′) may be configured to receive a second voltage (i.e., a second gate signal) different from the first voltage. For example, the lower gate structure 170b′ may be configured to receive the first voltage via the lower gate contact 142, and the upper gate structure 170a′ may be configured to receive the second voltage via the upper gate contact 148. In some embodiments, the first voltage may be a drain voltage Vdd, and the second voltage may be a source voltage Vss, but the present disclosure is not limited thereto.

The upper gate contact 148 extends into the first insulating layer 152 and is electrically connected to the upper gate structure 170a′ (e.g., to the upper conductive gate 174a′). For example, the upper gate contact 148 may be on an upper surface of the upper gate structure 170a′ (e.g., may be on an upper surface of the upper conductive gate 174a′). The lower gate contact 142 extends into the substrate 110 and the interlayer 122 and is electrically connected to the lower gate structure 170b′ (e.g., to the lower conductive gate 174b′). For example, the lower gate contact 142 may be on a lower surface of the lower gate structure 170b′ (e.g., may be on a lower surface of the lower conductive gate 174b′). The upper gate contact 148 and the lower gate contact 142 may each include a metal layer or material including, for example, W, Al, Cu, Mo, Co and/or Ru.

The MOSCAP 102 may operate as a voltage-controlled capacitor that relies on the capacitance between the lower conductive gate 174b′ and the lower channel layers 120b of the lower semiconductor device Sb, and the capacitance between the upper conductive gate 174a′ and the upper channel layers 120a of the upper semiconductor device Sa. In more detail, the lower conductive gate 174b′ and the lower channel layers 120b may form a capacitor, while the gate insulation layer (not shown) acts as a dielectric between the lower conductive gate 174b′ and the lower channel layers 120b. Likewise, the upper conductive gate 174a′ and the upper channel layers 120a may form a capacitor, while the gate insulation layer (not shown) acts as a dielectric between the upper conductive gate 174a′ and the upper channel layers 120a. In some embodiments, the lower and upper conductive gates 174b′, 174a′ may include a metal material, the gate insulation layer may include an oxide insulating material (e.g., silicon oxide, although embodiments of the present disclosure are not limited thereto), and the lower and upper channel layers 120b, 120a may include a semiconductor material, hence the name metal-oxide-semiconductor capacitor (MOSCAP). The capacitance of the MOSCAP 102 can be varied based on respective voltages applied to the lower gate structure 170b′ (e.g., to the lower conductive gate 174b′) and to the upper gate structure 170a′ (e.g., to the upper conductive gate 174a′).

As shown in FIG. 3C, the MOSCAP 102 is electrically connected between a frontside metal-oxide-metal capacitor (MOMCAP) 104 and a backside MOMCAP 106. For example, the upper structure 146 and the BSPDN structure 144 described above with reference to FIGS. 2B-D may be reconfigured to provide the frontside MOMCAP 104 and the backside MOMCAP 106, respectively. The frontside MOMCAP 104 may be provided on the first surface S1 (i.e., the frontside) of the substrate 110. For example, the frontside MOMCAP 104 may be provided on the MOSCAP 102 (e.g., on an upper surface of the MOSCAP 102). The backside MOMCAP 106 may be provided on the second surface S2 (i.e., the backside) of the substrate 110. For example, the backside MOMCAP 106 may be provided on a lower surface of the MOSCAP 102. The MOSCAP 102 is between, in the third direction Z, the frontside MOMCAP 104 and the backside MOMCAP 106. For example, the MOSCAP 102, the frontside MOMCAP 104, and the backside MOMCAP 106 may overlap with each other in the third direction Z.

In some embodiments, the conductive elements and insulating elements included in the upper structure 146 of FIGS. 2B-D may be reconfigured to provide the frontside MOMCAP 104. For example, the frontside MOMCAP 104 may be formed in a vertical direction (e.g., the third direction Z) while utilizing (or reconfiguring) the existing (i.e., natural) elements of the upper structure 146 to form the frontside MOMCAP 104, and thus the frontside MOMCAP 104 may also be referred to herein as a “frontside vertical natural capacitor (VNCAP).” For example, the frontside MOMCAP 104 may be formed as part of the fabrication process for the integrated circuit device 100 of FIGS. 2B-D by reconfiguring the upper structure 146. In some embodiments, the conductive elements of the frontside MOMCAP 104 may be formed during the back-end-of-line (BEOL) portion of device fabrication, using, for example, frontside signal patterns.

In some embodiments, the conductive elements and insulating elements included in the BSPDN structure 144 of FIGS. 2B-D may be reconfigured to provide the backside MOMCAP 106. For example, the backside MOMCAP 106 may be formed in a vertical direction (e.g., the third direction Z) while utilizing (or reconfiguring) the existing (i.e., natural) elements of the BSPDN structure 144 to form the backside MOMCAP 106, and thus the backside MOMCAP 106 may also be referred to herein as a “backside vertical natural capacitor (VNCAP).” For example, the backside MOMCAP 106 may be formed as part of the fabrication process for the integrated circuit device 100 of FIGS. 2B-D by reconfiguring the BSPDN structure 144. In some embodiments, the conductive elements of the backside MOMCAP 106 may be formed through the back-end-of-line (BEOL) portion of device fabrication, using, for example, backside signal patterns instead of backside power patterns. For example, the pitch of conductive patterns used for signal lines may be finer (i.e., smaller) than that used for power lines, allowing for the density of the backside MOMCAP 106 to be increased by utilizing the finer-pitch signal patterns. A minimum width of conductive elements included in the backside MOMCAP 106 may thus be reduced, as well as a minimum spacing (i.e., a minimum distance) between conductive elements included in the backside MOMCAP 106. In other embodiments, the conductive elements of the backside MOMCAP 106 may be formed using, for example, backside power patterns.

As shown in FIG. 3C, the frontside MOMCAP 104 includes a lower frontside metallization pattern 160. The lower frontside metallization pattern 160 may include a first lower frontside metallization layer 160a and a second lower frontside metallization layer 160b. The first lower frontside metallization layer 160a may include a plurality of first lower frontside fingers 160a-1. The second lower frontside metallization layer 160b may include a plurality of second lower frontside fingers 160b-1. As used herein, the plurality of first lower frontside fingers 160a-1 and the plurality of second lower frontside fingers 160b-1 may be collectively referred to as a plurality of interdigitated lower frontside fingers 160a-1, 160b-1. The frontside MOMCAP 104 may further include a second insulating layer 154 that extends between the first lower frontside metallization layer 160a and the second lower frontside metallization layer 160b. The lower frontside metallization pattern 160 may include a metal layer or material including, for example, W, Al, Cu, Mo, Co and/or Ru. The second insulating layer 154 may include insulating material(s) (e.g., silicon oxide, silicon oxynitride, silicon nitride, silicon carbonitride and/or a low-k material). Although the second insulating layer 154 is illustrated as a single layer, in some embodiments, the second insulating layer 154 may include multiple layers.

The first lower frontside metallization layer 160a (or the first lower frontside fingers 160a-1) and the second lower frontside metallization layer 160b (or the second lower frontside fingers 160b-1) can be thought of as the conductive plates of the frontside MOMCAP 104, with the second insulating layer 154 therebetween. A capacitance may thus be formed between the first lower frontside metallization layer 160a and the second lower frontside metallization layer 160b of the frontside MOMCAP 104. In some embodiments, the first lower frontside metallization layer 160a includes a metal material, the second insulating layer 154 includes an oxide insulating material (e.g., silicon oxide and/or aluminum oxide, although embodiments of the present disclosure are not limited thereto), and the second lower frontside metallization layer 160b includes a metal material, hence the name metal-oxide-metal capacitor (MOMCAP). The frontside MOMCAP 104 will be described in greater detail below with reference to FIGS. 3F and 3G.

The MOSCAP 102 may be electrically connected to the frontside MOMCAP 104. For example, the upper gate structure 170a′ (e.g., the upper conductive gate 174a′) may be electrically connected to the frontside MOMCAP 104 through the upper gate contact 148. A first electrical path 191-1 (shown by a dashed box in FIG. 3C) may be provided between the frontside MOMCAP 104 and the MOSCAP 102. The upper gate structure 170a′ (e.g., the upper conductive gate 174a′) may be electrically connected to a second voltage along the first electrical path 191-1. For example, the second lower frontside metallization layer 160b may be configured to receive the second voltage. In some embodiments, the second voltage may be a source voltage Vss, but the present disclosure is not limited thereto. For example, the first electrical path 191-1 may correspond to an output path of the MOSCAP 102, frontside MOMCAP 104, and backside MOMCAP 106, but the present disclosure is not limited thereto.

Still referring to FIG. 3C, the backside MOMCAP 106 includes an upper backside metallization pattern 180. The upper backside metallization pattern 180 may include a first upper backside metallization layer 180a and a second upper backside metallization layer 180b. The first upper backside metallization layer 180a may include a plurality of first upper backside fingers 180a-1. The second upper backside metallization layer 180b may include a plurality of second upper backside fingers 180b-1. As used herein, the plurality of first upper backside fingers 180a-1 and the plurality of second upper backside fingers 180b-1 may be collectively referred to as a plurality of interdigitated upper backside fingers 180a-1, 180b-1. The backside MOMCAP 106 may further include a third insulating layer 194 that extends between the first upper backside metallization layer 180a and the second upper backside metallization layer 180b. The upper backside metallization pattern 180 may include a metal layer or material including, for example, W, Al, Cu, Mo, Co and/or Ru. The third insulating layer 194 may include insulating material(s) (e.g., silicon oxide, silicon oxynitride, silicon nitride, silicon carbonitride and/or a low-k material). Although the third insulating layer 194 is illustrated as a single layer, in some embodiments, the third insulating layer 194 may include multiple layers.

The first upper backside metallization layer 180a (or the first upper backside fingers 180a-1) and the second upper backside metallization layer 180b (or the second upper backside fingers 180b-1) can be thought of as the conductive plates of the backside MOMCAP 106, with the third insulating layer 194 therebetween. A capacitance may thus be formed between the first upper backside metallization layer 180a and the second upper backside metallization layer 180b of the backside MOMCAP 106. In some embodiments, the first upper backside metallization layer 180a includes a metal material, the third insulating layer 194 includes an oxide insulating material (e.g., silicon oxide and/or aluminum oxide, although embodiments of the present disclosure are not limited thereto), and the second upper backside metallization layer 180b includes a metal material, hence the name metal-oxide-metal capacitor (MOMCAP). The backside MOMCAP 106 will be described in greater detail below with reference to FIGS. 3H and 3I.

The MOSCAP 102 may be electrically connected to the backside MOMCAP 106. For example, the lower gate structure 170b′ (e.g., the lower conductive gate 174b′) may be electrically connected to the backside MOMCAP 106 through the lower gate contact 142. A second electrical path 192-1 (shown by a dashed box in FIG. 3C) may be provided between the backside MOMCAP 106 and the MOSCAP 102. The lower gate structure 170b′ (e.g., the lower conductive gate 174b′) may be electrically connected to a first voltage along the second electrical path 192-1. For example, the first upper backside metallization layer 180a may be configured to receive the first voltage. In some embodiments, the first voltage may be a drain voltage Vdd, but the present disclosure is not limited thereto. For example, the second electrical path 192-1 may correspond to an input path of the MOSCAP 102, frontside MOMCAP 104, and backside MOMCAP 106, but the present disclosure is not limited thereto.

FIG. 3D is a schematic cross-sectional view taken along line C-C′ of FIG. 3B. FIG. 3E is a schematic cross-sectional view taken along line D-D′ of FIG. 3B. Referring to FIGS. 3B, 3D, and 3E, the pair of upper source/drain regions 150 of the MOSCAP 102 may be electrically connected to both the frontside MOMCAP 104 and the backside MOMCAP 106. Likewise, the pair of lower source/drain regions 140 of the MOSCAP 102 may be electrically connected to both the frontside MOMCAP 104 and the backside MOMCAP 106. In some embodiments, a width of each of the pair of lower source/drain regions 140 in the second direction Y may be greater than a width of each of the pair of upper source/drain regions 150 in the second direction Y.

As shown in FIG. 3D, a first one of the pair of upper source/drain regions 150 may be electrically connected to both the frontside MOMCAP 104 and the backside MOMCAP 106 through a first upper source/drain contact structure 133a. The first upper source/drain contact structure 133a may extend into the substrate 110, the interlayer 122, and the first insulating layer 152. For example, the first upper source/drain contact structure 133a may extend between the frontside MOMCAP 104 and the backside MOMCAP 106 (e.g., in the third direction Z). The first upper source/drain contact structure 133a may include a first upper conductive plug 158a, a first source/drain contact 108a, a first middle conductive plug 114a, and a first lower conductive plug 118a. The first source/drain contact 108a may be in contact with (e.g., may be in electrical contact with) the first one of the pair of upper source/drain regions 150. For example, the first source/drain contact 108a may be on and in contact with an upper surface of the first one of the pair of upper source/drain regions 150. The first lower conductive plug 118a is electrically connected between the backside MOMCAP 106 and the first middle conductive plug 114a. For example, the first lower conductive plug 118a may be in contact with (e.g., may be in electrical contact with) the backside MOMCAP 106, according to some embodiments. The first middle conductive plug 114a may be electrically connected between (e.g., in the third direction Z) the first source/drain contact 108a and the first lower conductive plug 118a. The first upper conductive plug 158a is electrically connected between the frontside MOMCAP 104 and the first source/drain contact 108a. For example, the first upper conductive plug 158a may be in contact with (e.g., may be in electrical contact with) the frontside MOMCAP 104, according to some embodiments. The first upper source/drain contact structure 133a may thus be electrically connected to the first one of the pair of upper source/drain regions 150, the frontside MOMCAP 104, and the backside MOMCAP 106. The first upper conductive plug 158a, the first source/drain contact 108a, the first middle conductive plug 114a, and the first lower conductive plug 118a may each include a metal layer or material including, for example, W, Al, Cu, Mo, Co and/or Ru.

A third electrical path 192-2 (shown by a dashed box in FIG. 3D) may be provided between the frontside MOMCAP 104 and the MOSCAP 102, and between the backside MOMCAP 106 and the MOSCAP 102. The first one of the pair of upper source/drain regions 150 may be electrically connected to a first voltage along the third electrical path 192-2. For example, the first lower frontside metallization layer 160a of the frontside MOMCAP 104 and/or the first upper backside metallization layer 180a of the backside MOMCAP 106 may be configured to receive the first voltage. In some embodiments, the first voltage may be a drain voltage Vdd, but the present disclosure is not limited thereto. For example, the third electrical path 192-2 may correspond to an input path of the MOSCAP 102, frontside MOMCAP 104, and backside MOMCAP 106, but the present disclosure is not limited thereto.

As shown in FIGS. 3C and 3D, the lower gate structure 170b′ (e.g., the lower conductive gate 174b′) is electrically connected to the first upper backside metallization layer 180a of the backside MOMCAP 106 along the second electrical path 192-1, while the first one of the pair of upper source/drain regions 150 is electrically connected to the first upper backside metallization layer 180a of the backside MOMCAP 106 along the third electrical path 192-2. The lower gate structure 170b′ (e.g., the lower conductive gate 174b′) may thus be electrically connected to the first one of the pair of upper source/drain regions 150. That is, the lower gate structure 170b′ of the MOSCAP 102 may be electrically shorted to the first one of the pair of upper source/drain regions 150 of the MOSCAP 102. Said another way, the MOSCAP 102 may be formed, in part, by electrically connecting the lower gate structure 170b′ of the lower semiconductor device Sb (see FIG. 3A) to the first one of the pair of upper source/drain regions 150 of the upper semiconductor device Sa (see FIG. 3A).

As shown in FIG. 3E, a second one of the pair of upper source/drain regions 150 may be electrically connected to both the frontside MOMCAP 104 and the backside MOMCAP 106 through a second upper source/drain contact structure 133b. The second upper source/drain contact structure 133b may extend into the substrate 110, the interlayer 122, and the first insulating layer 152. For example, the second upper source/drain contact structure 133b may extend between the frontside MOMCAP 104 and the backside MOMCAP 106 (e.g., in the third direction Z). The second upper source/drain contact structure 133b may include a second upper conductive plug 158b, a second source/drain contact 108b, a second middle conductive plug 114b, and a second lower conductive plug 118b. The second source/drain contact 108b may be in contact with (e.g., may be in electrical contact with) the second one of the pair of upper source/drain regions 150. For example, the second source/drain contact 108b may be on and in contact with an upper surface of the second one of the pair of upper source/drain regions 150. The second lower conductive plug 118b is electrically connected between the backside MOMCAP 106 and the second middle conductive plug 114b. For example, the second lower conductive plug 118b may be in contact with (e.g., may be in electrical contact with) the backside MOMCAP 106, according to some embodiments. The second middle conductive plug 114b may be electrically connected between (e.g., in the third direction Z) the second source/drain contact 108b and the second lower conductive plug 118b. The second upper conductive plug 158b is electrically connected between the frontside MOMCAP 104 and the second source/drain contact 108b. For example, the second upper conductive plug 158b may be in contact with (e.g., may be in electrical contact with) the frontside MOMCAP 104, according to some embodiments. The second upper source/drain contact structure 133b may thus be electrically connected to the second one of the pair of upper source/drain regions 150, the frontside MOMCAP 104, and the backside MOMCAP 106. The second upper conductive plug 158b, the second source/drain contact 108b, the second middle conductive plug 114b, and the second lower conductive plug 118b may each include a metal layer or material including, for example, W, Al, Cu, Mo, Co and/or Ru.

A fourth electrical path 192-3 (shown by a dashed box in FIG. 3E) may be provided between the frontside MOMCAP 104 and the MOSCAP 102, and between the backside MOMCAP 106 and the MOSCAP 102. The second one of the pair of upper source/drain regions 150 may be electrically connected to a first voltage along the fourth electrical path 192-3. For example, the first lower frontside metallization layer 160a of the frontside MOMCAP 104 and/or the first upper backside metallization layer 180a of the backside MOMCAP 106 may be configured to receive the first voltage. In some embodiments, the first voltage may be a drain voltage Vdd, but the present disclosure is not limited thereto. For example, the fourth electrical path 192-3 may correspond to an input path of the MOSCAP 102, frontside MOMCAP 104, and backside MOMCAP 106, but the present disclosure is not limited thereto.

As shown in FIGS. 3C and 3E, the lower gate structure 170b′ (e.g., the lower conductive gate 174b′) is electrically connected to the first upper backside metallization layer 180a of the backside MOMCAP 106 along the second electrical path 192-1, while the second one of the pair of upper source/drain regions 150 is electrically connected to the first upper backside metallization layer 180a of the backside MOMCAP 106 along the fourth electrical path 192-3. The lower gate structure 170b′ (e.g., the lower conductive gate 174b′) may thus be electrically connected to the second one of the pair of upper source/drain regions 150. That is, the lower gate structure 170b′ of the MOSCAP 102 may be electrically shorted to the second one of the pair of upper source/drain regions 150 of the MOSCAP 102. Said another way, the MOSCAP 102 may be formed, in part, by electrically connecting the lower gate structure 170b′ of the lower semiconductor device Sb (see FIG. 3A) to the second one of the pair of upper source/drain regions 150 of the upper semiconductor device Sa (see FIG. 3A).

As described above, the pair of upper source/drain regions 150 of the MOSCAP 102 may both be electrically connected to the lower gate structure 170b′ of the MOSCAP 102. In other words, the pair of upper source/drain regions 150 of the upper semiconductor device Sa included in the MOSCAP 102 may both be electrically connected to the lower gate structure 170b′ of the lower semiconductor device Sb included in the MOSCAP 102.

As shown in FIG. 3D, a first one of the pair of lower source/drain regions 140 may be electrically connected to both the frontside MOMCAP 104 and the backside MOMCAP 106 through a first lower source/drain contact structure 134a. The first lower source/drain contact structure 134a may extend into the substrate 110, the interlayer 122, and the first insulating layer 152. For example, the first lower source/drain contact structure 134a may extend between the frontside MOMCAP 104 and the backside MOMCAP 106 (e.g., in the third direction Z). The first lower source/drain contact structure 134a may include a third upper conductive plug 156a, a first conductive line 132a, a third middle conductive plug 116a, a third source/drain contact 112a, and a fourth source/drain contact 124a.

The third source/drain contact 112a may be in contact with (e.g., may be in electrical contact with) the first one of the pair of lower source/drain regions 140. For example, the third source/drain contact 112a may be on and in contact with an upper surface of the first one of the pair of lower source/drain regions 140. The fourth source/drain contact 124a may also be in contact with (e.g., may be in electrical contact with) the first one of the pair of lower source/drain regions 140. For example, the fourth source/drain contact 124a may be on and in contact with a lower surface of the first one of the pair of lower source/drain regions 140. A contact area between the first lower source/drain contact structure 134a and the first one of the pair of lower source/drain regions 140 may be increased by providing both the third source/drain contact 112a that is on the upper surface of the first one of the pair of lower source/drain regions 140 and is electrically connected thereto, and the fourth source/drain contact 124a that is on the lower surface of the first one of the pair of lower source/drain regions 140 and is electrically connected thereto. Accordingly, a resistance between the first lower source/drain contact structure 134a and the first one of the pair of lower source/drain regions 140 may be reduced, thereby reducing power loss during operation of the integrated circuit device 100a.

The fourth source/drain contact 124a is electrically connected between the backside MOMCAP 106 and the first one of the pair of lower source/drain regions 140. For example, the fourth source/drain contact 124a may be in contact with (e.g., may be in electrical contact with) the backside MOMCAP 106, according to some embodiments. The third upper conductive plug 156a is electrically connected between the frontside MOMCAP 104 and the first conductive line 132a. For example, the third upper conductive plug 156a may be in contact with (e.g., may be in electrical contact with) the frontside MOMCAP 104, according to some embodiments. The first conductive line 132a and the third middle conductive plug 116a may be electrically connected between the third upper conductive plug 156a and the third source/drain contact 112a. For example, the first conductive line 132a may extend in a horizontal direction (e.g., the second direction Y), and the third middle conductive plug 116a may extend in a vertical direction (e.g., the third direction Z). The first lower source/drain contact structure 134a may be electrically connected to the first one of the pair of lower source/drain regions 140, the frontside MOMCAP 104, and the backside MOMCAP 106. The third upper conductive plug 156a, the first conductive line 132a, the third middle conductive plug 116a, the third source/drain contact 112a, and the fourth source/drain contact 124a may each include a metal layer or material including, for example, W, Al, Cu, Mo, Co and/or Ru.

A fifth electrical path 191-2 (shown by a dashed box in FIG. 3D) may be provided between the frontside MOMCAP 104 and the MOSCAP 102, and between the backside MOMCAP 106 and the MOSCAP 102. The first one of the pair of lower source/drain regions 140 may be electrically connected to a second voltage along the fifth electrical path 191-2. For example, the second lower frontside metallization layer 160b of the frontside MOMCAP 104 and/or the second upper backside metallization layer 180b of the backside MOMCAP 106 may be configured to receive the second voltage. In some embodiments, the second voltage may be a source voltage Vss, but the present disclosure is not limited thereto. For example, the fifth electrical path 191-2 may correspond to an output path of the MOSCAP 102, frontside MOMCAP 104, and backside MOMCAP 106, but the present disclosure is not limited thereto.

As shown in FIGS. 3C and 3D, the upper gate structure 170a′ (e.g., the upper conductive gate 174a′) is electrically connected to the second lower frontside metallization layer 160b of the frontside MOMCAP 104 along the first electrical path 191-1, while the first one of the pair of lower source/drain regions 140 is electrically connected to the second lower frontside metallization layer 160b of the frontside MOMCAP 104 along the fifth electrical path 191-2. The upper gate structure 170a′ (e.g., the upper conductive gate 174a′) may thus be electrically connected to the first one of the pair of lower source/drain regions 140. That is, the upper gate structure 170a′ of the MOSCAP 102 may be electrically shorted to the first one of the pair of lower source/drain regions 140 of the MOSCAP 102. Said another way, the MOSCAP 102 may be formed, in part, by electrically connecting the upper gate structure 170a′ of the upper semiconductor device Sa (see FIG. 3A) to the first one of the pair of lower source/drain regions 140 of the lower semiconductor device Sb (see FIG. 3A).

As shown in FIG. 3E, a second one of the pair of lower source/drain regions 140 may be electrically connected to both the frontside MOMCAP 104 and the backside MOMCAP 106 through a second lower source/drain contact structure 134b. The second lower source/drain contact structure 134b may extend into the substrate 110, the interlayer 122, and the first insulating layer 152. For example, the second lower source/drain contact structure 134b may extend between the frontside MOMCAP 104 and the backside MOMCAP 106 (e.g., in the third direction Z). The second lower source/drain contact structure 134b may include a fourth upper conductive plug 156b, a second conductive line 132b, a fourth middle conductive plug 116b, a fifth source/drain contact 112b, and a sixth source/drain contact 124b.

The fifth source/drain contact 112b may be in contact with (e.g., may be in electrical contact with) the second one of the pair of lower source/drain regions 140. For example, the fifth source/drain contact 112b may be on and in contact with an upper surface of the second one of the pair of lower source/drain regions 140. The sixth source/drain contact 124b may also be in contact with (e.g., may be in electrical contact with) the second one of the pair of lower source/drain regions 140. For example, the sixth source/drain contact 124b may be on and in contact with a lower surface of the second one of the pair of lower source/drain regions 140. A contact area between the second lower source/drain contact structure 134b and the second one of the pair of lower source/drain regions 140 may be increased by providing both the fifth source/drain contact 112b that is on the upper surface of the second one of the pair of lower source/drain regions 140 and is electrically connected thereto, and the sixth source/drain contact 124b that is on the lower surface of the second one of the pair of lower source/drain regions 140 and is electrically connected thereto. Accordingly, a resistance between the second lower source/drain contact structure 134b and the second one of the pair of lower source/drain regions 140 may be reduced, thereby reducing power loss during operation of the integrated circuit device 100a.

The sixth source/drain contact 124b is electrically connected between the backside MOMCAP 106 and the second one of the pair of lower source/drain regions 140. For example, the sixth source/drain contact 124b may be in contact with (e.g., may be in electrical contact with) the backside MOMCAP 106, according to some embodiments. The fourth upper conductive plug 156b is electrically connected between the frontside MOMCAP 104 and the second conductive line 132b. For example, the fourth upper conductive plug 156b may be in contact with (e.g., may be in electrical contact with) the frontside MOMCAP 104, according to some embodiments. The second conductive line 132b and the fourth middle conductive plug 116b may be electrically connected between the fourth upper conductive plug 156b and the fifth source/drain contact 112b. For example, the second conductive line 132b may extend in a horizontal direction (e.g., the second direction Y), and the fourth middle conductive plug 116b may extend in a vertical direction (e.g., the third direction Z). The second lower source/drain contact structure 134b may be electrically connected to the second one of the pair of lower source/drain regions 140, the frontside MOMCAP 104, and the backside MOMCAP 106. The fourth upper conductive plug 156b, the second conductive line 132b, the fourth middle conductive plug 116b, the fifth source/drain contact 112b, and the sixth source/drain contact 124b may each include a metal layer or material including, for example, W, Al, Cu, Mo, Co and/or Ru.

A sixth electrical path 191-3 (shown by a dashed box in FIG. 3E) may be provided between the frontside MOMCAP 104 and the MOSCAP 102, and between the backside MOMCAP 106 and the MOSCAP 102. The second one of the pair of lower source/drain regions 140 may be electrically connected to a second voltage along the sixth electrical path 191-3. For example, the second lower frontside metallization layer 160b of the frontside MOMCAP 104 and/or the second upper backside metallization layer 180b of the backside MOMCAP 106 may be configured to receive the second voltage. In some embodiments, the second voltage may be a source voltage Vss, but the present disclosure is not limited thereto. For example, the sixth electrical path 191-3 may correspond to an output path of the MOSCAP 102, frontside MOMCAP 104, and backside MOMCAP 106, but the present disclosure is not limited thereto.

As shown in FIGS. 3C and 3E, the upper gate structure 170a′ (e.g., the upper conductive gate 174a′) is electrically connected to the second lower frontside metallization layer 160b of the frontside MOMCAP 104 along the first electrical path 191-1, while the second one of the pair of lower source/drain regions 140 is electrically connected to the second lower frontside metallization layer 160b of the frontside MOMCAP 104 along the sixth electrical path 191-3. The upper gate structure 170a′ (e.g., the upper conductive gate 174a′) may thus be electrically connected to the second one of the pair of lower source/drain regions 140. That is, the upper gate structure 170a′ of the MOSCAP 102 may be electrically shorted to the second one of the pair of lower source/drain regions 140 of the MOSCAP 102. Said another way, the MOSCAP 102 may be formed, in part, by electrically connecting the upper gate structure 170a′ of the upper semiconductor device Sa (see FIG. 3A) to the second one of the pair of lower source/drain regions 140 of the lower semiconductor device Sb (see FIG. 3A).

As described above, the pair of lower source/drain regions 140 of the MOSCAP 102 may both be electrically connected to the upper gate structure 170a′ of the MOSCAP 102. In other words, the pair of lower source/drain regions 140 of the lower semiconductor device Sb included in the MOSCAP 102 may both be electrically connected to the upper gate structure 170a′ of the upper semiconductor device Sa included in the MOSCAP 102.

FIG. 3F is a schematic plan view of a frontside MOMCAP according to some embodiments. Like reference numerals refer to like elements. For simplicity of description, repeated descriptions of like elements described above may be omitted.

Referring to FIG. 3F, the frontside MOMCAP 104 includes the lower frontside metallization pattern 160. The lower frontside metallization pattern 160 may include the first lower frontside metallization layer 160a and the second lower frontside metallization layer 160b. The second insulating layer 154 may extend between the first lower frontside metallization layer 160a and the second lower frontside metallization layer 160b. For example, the second insulating layer 154 may insulate (i.e., isolate) the first lower frontside metallization layer 160a from the second lower frontside metallization layer 160b. In some embodiments, the first lower frontside metallization layer 160a may be configured to receive a first voltage (e.g., a drain voltage Vdd), and the second lower frontside metallization layer 160b may be configured to receive a second voltage (e.g., a source voltage Vss).

The first lower frontside metallization layer 160a may include the plurality of first lower frontside fingers 160a-1 and a first lower frontside conductive plate 160a-2. The first lower frontside fingers 160a-1 may extend (e.g., may longitudinally extend) in the first direction X from the first lower frontside conductive plate 160a-2. For example, the first lower frontside conductive plate 160a-2 may act as a common electrical path for the first lower frontside fingers 160a-1, and may share the first voltage with the first lower frontside fingers 160a-1. In some embodiments, a longest dimension of the first lower frontside fingers 160a-1 may be in the first direction X.

The second lower frontside metallization layer 160b may include the plurality of second lower frontside fingers 160b-1 and a second lower frontside conductive plate 160b-2. The second lower frontside fingers 160b-1 may extend (e.g., may longitudinally extend) in the first direction X (e.g., opposite the first lower frontside fingers 160a-1) from the second lower frontside conductive plate 160b-2. For example, the second lower frontside conductive plate 160b-2 may act as a common electrical path for the second lower frontside fingers 160b-1, and may share the second voltage with the second lower frontside fingers 160b-1. In some embodiments, a longest dimension of the second lower frontside fingers 160b-1 may be in the first direction X.

The first lower frontside fingers 160a-1 and the second lower frontside fingers 160b-1 may be interdigitated (e.g., may resemble an interlocking structure, such as the fingers of clasped hands), and thus the first lower frontside fingers 160a-1 and the second lower frontside fingers 160b-1 may be collectively referred to as interdigitated lower frontside fingers 160a-1, 160b-1. As shown in FIG. 3F, the second insulating layer 154 extends between adjacent ones of the Interdigitated lower frontside fingers 160a-1, 160b-1, and a capacitance (shown by a capacitor symbol in FIG. 3F) may thus be formed between the adjacent ones of the interdigitated lower frontside fingers 160a-1, 160b-1 (e.g., in the second direction Y). The interdigitated lower frontside fingers 160a-1, 160b-1 may extend in the first direction X and may be spaced apart from each other in the second direction Y. The first lower frontside fingers 160a-1 and the second lower frontside fingers 160b-1 may not be galvanically coupled to each other (e.g., may not have a direct electrical connection therebetween) and instead may only be capacitively coupled to each other. In other words, the first lower frontside metallization layer 160a and the second lower frontside metallization layer 160b may not be galvanically coupled to each other (e.g., may not have a direct electrical connection therebetween) and instead may only be capacitively coupled to each other. Although FIG. 3F illustrates eleven interdigitated lower frontside fingers 160a-1, 160b-1, the present disclosure is not limited thereto. In other embodiments, the frontside MOMCAP 104 may include more than eleven interdigitated lower frontside fingers 160a-1, 160b-1 or less than eleven interdigitated lower frontside fingers 160a-1, 160b-1.

In some embodiments, a minimum width (e.g., according to predefined design rules) may be used for the lower frontside metallization pattern 160 to increase the capacitance density (i.e., to increase the amount of capacitance per unit area) of the frontside MOMCAP 104. For example, each of the interdigitated lower frontside fingers 160a-1, 160b-1 may have a width in the second direction Y that is less than 100 nanometers (nm). In some embodiments, a minimum spacing (e.g., according to predefined design rules) between the first lower frontside metallization layer 160a and the second lower frontside metallization layer 160b of the frontside MOMCAP 104 may be used to increase the capacitance density of the frontside MOMCAP 104. For example, adjacent ones of the interdigitated lower frontside fingers 160a-1, 160b-1 (e.g., a respective one of the first lower frontside fingers 160a-1 that is adjacent to a respective one of the second lower frontside fingers 160b-1) may be spaced apart from each other by less than 100 nanometers (nm) in the second direction Y. In other words, a distance in the second direction Y between adjacent ones of the interdigitated lower frontside fingers 160a-1, 160b-1 may be less than 100 nanometers (nm).

FIG. 3G is a schematic plan view of an integrated circuit device including the frontside MOMCAP of FIG. 3F according to some embodiments. For simplicity of illustration, FIG. 3G only shows some elements of the integrated circuit device 100a. To help illustrate example embodiments of the present disclosure, the lines B-B′, C-C′, and D-D′ corresponding to the cross-sectional views of FIG. 3C, FIG. 3D, and FIG. 3E, respectively, are shown in the plan view of FIG. 3G. Like reference numerals refer to like elements. For simplicity of description, repeated descriptions of like elements described above may be omitted.

As shown in FIG. 3G, the integrated circuit device 100a may include a plurality of unit cells 100a-1 to 100a-4. For example, a first unit cell 100a-1 of the integrated circuit device 100a may correspond to the plan view of the integrated circuit device 100a shown in FIG. 3B. Although FIG. 3G illustrates four unit cells 100a-1 to 100a-4, the present disclosure is not limited thereto. In other embodiments, the integrated circuit device 100a may include more than four unit cells or less than four unit cells.

As shown in FIG. 3G, the interdigitated lower frontside fingers 160a-1, 160b-1 may extend (e.g., may longitudinally extend) in the first direction X, and the gate structures 170′ (and the upper and lower gate structures 170a′ and 170b′ included therein) may extend (e.g., may longitudinally extend) in the second direction Y. For example, a longest dimension of the interdigitated lower frontside fingers 160a-1, 160b-1 may be in the first direction X, and a longest dimension of the gate structures 170′ (and the upper and lower gate structures 170a′ and 170b′ included therein) may be in the second direction Y, although embodiments of the present disclosure are not limited thereto. For example, the interdigitated lower frontside fingers 160a-1, 160b-1 may extend perpendicular to the gate structures 170′ (and the upper and lower gate structures 170a′ and 170b′ included therein). The interdigitated lower frontside fingers 160a-1, 160b-1 may overlap the gate structures 170′ (and the upper and lower gate structures 170a′ and 170b′ included therein) in the third direction Z. The interdigitated lower frontside fingers 160a-1, 160b-1 may also overlap the first, second, third, and fourth upper conductive plugs 158a, 158b, 156a, and 156b and the lower and upper gate contacts 142 and 148 in the third direction Z. For example, ones of the first lower frontside fingers 160a-1 may overlap the first and second upper conductive plugs 158a, 158b and the lower gate contacts 142 (shown by a dotted line box in FIG. 3G) in the third direction Z, and ones of the second lower frontside fingers 160b-1 may overlap the third and fourth upper conductive plugs 156a, 156b and the upper gate contacts 148 in the third direction Z.

FIG. 3H is a schematic plan view of a backside MOMCAP according to some embodiments. Like reference numerals refer to like elements. For simplicity of description, repeated descriptions of like elements described above may be omitted.

Referring to FIG. 3H, the backside MOMCAP 106 includes the upper backside metallization pattern 180. The upper backside metallization pattern 180 may include the first upper backside metallization layer 180a and the second upper backside metallization layer 180b. The third insulating layer 194 may extend between the first upper backside metallization layer 180a and the second upper backside metallization layer 180b. For example, the third insulating layer 194 may insulate (i.e., isolate) the first upper backside metallization layer 180a from the second upper backside metallization layer 180b. In some embodiments, the first upper backside metallization layer 180a of the backside MOMCAP 106 may be configured to receive a first voltage (e.g., a drain voltage Vdd), and the second upper backside metallization layer 180b may be configured to receive a second voltage (e.g., a source voltage Vss).

The first upper backside metallization layer 180a may include the plurality of first upper backside fingers 180a-1 and a first upper backside conductive plate 180a-2. The first upper backside fingers 180a-1 may extend (e.g., may longitudinally extend) in the first direction X from the first upper backside conductive plate 180a-2. For example, the first upper backside conductive plate 180a-2 may act as a common electrical path for the first upper backside fingers 180a-1, and may share the first voltage with the first upper backside fingers 180a-1. In some embodiments, a longest dimension of the first upper backside fingers 180a-1 may be in the first direction X.

The second upper backside metallization layer 180b may include the plurality of second upper backside fingers 180b-1 and a second upper backside conductive plate 180b-2. The second upper backside fingers 180b-1 may extend (e.g., may longitudinally extend) in the first direction X (e.g., opposite the first upper backside fingers 180a-1) from the second upper backside conductive plate 180b-2. For example, the second upper backside conductive plate 180b-2 may act as a common electrical path for the second upper backside fingers 180b-1, and may share the second voltage with the second upper backside fingers 180b-1. In some embodiments, a longest dimension of the second upper backside fingers 180b-1 may be in the first direction X.

The first upper backside fingers 180a-1 and the second upper backside fingers 180b-1 may be interdigitated (e.g., may resemble an interlocking structure, such as the fingers of clasped hands), and thus the first upper backside fingers 180a-1 and the second upper backside fingers 180b-1 may be collectively referred to as interdigitated upper backside fingers 180a-1, 180b-1. As shown in FIG. 3H, the third insulating layer 194 extends between adjacent ones of the interdigitated upper backside fingers 180a-1, 180b-1, and a capacitance (shown by a capacitor symbol in FIG. 3H) may thus be formed between the adjacent ones of the interdigitated upper backside fingers 180a-1, 180b-1 (e.g., in the second direction Y). The interdigitated upper backside fingers 180a-1, 180b-1 may extend in the first direction X and may be spaced apart from each other in the second direction Y. The first upper backside fingers 180a-1 and the second upper backside fingers 180b-1 may not be galvanically coupled to each other (e.g., may not have a direct electrical connection therebetween) and instead may only be capacitively coupled to each other. In other words, the first upper backside metallization layer 180a and the second upper backside metallization layer 180b may not be galvanically coupled to each other (e.g., may not have a direct electrical connection therebetween) and instead may only be capacitively coupled to each other. Although FIG. 3H illustrates eleven interdigitated upper backside fingers 180a-1, 180b-1, the present disclosure is not limited thereto. In other embodiments, the backside MOMCAP 106 may include more than eleven interdigitated upper backside fingers 180a-1, 180b-1 or less than eleven interdigitated upper backside fingers 180a-1, 180b-1.

In some embodiments, a minimum width (e.g., according to predefined design rules) may be used for the upper backside metallization pattern 180 to increase the capacitance density (i.e., to increase the amount of capacitance per unit area) of the backside MOMCAP 106. For example, each of the interdigitated upper backside fingers 180a-1, 180b-1 may have a width in the second direction Y that is less than 100 nanometers (nm). In some embodiments, a minimum spacing (e.g., according to predefined design rules) between the first upper backside metallization layer 180a and the second upper backside metallization layer 180b of the backside MOMCAP 106 may be used to increase the capacitance density of the backside MOMCAP 106. For example, adjacent ones of the interdigitated upper backside fingers 180a-1, 180b-1 (e.g., a respective one of the first upper backside fingers 180a-1 that is adjacent to a respective one of the second upper backside fingers 180b-1) may be spaced apart from each other by less than 100 nanometers (nm) in the second direction Y. In other words, a distance in the second direction Y between adjacent ones of the interdigitated upper backside fingers 180a-1, 180b-1 may be less than 100 nanometers (nm).

Referring to FIGS. 3F and 3H, in some embodiments, widths (e.g., in the second direction Y) of the interdigitated upper backside fingers 180a-1, 180b-1 of the backside MOMCAP 106 may be substantially equal to widths (e.g., in the second direction Y) of the interdigitated lower frontside fingers 160a-1, 160b-1 of the frontside MOMCAP 104. In some embodiments, a spacing or distance (e.g., in the second direction Y) between adjacent ones of the interdigitated upper backside fingers 180a-1, 180b-1 of the backside MOMCAP 106 may be substantially equal to a spacing or distance (e.g., in the second direction Y) between adjacent ones of the interdigitated lower frontside fingers 160a-1, 160b-1 of the frontside MOMCAP 104.

FIG. 3I is a schematic plan view of an integrated circuit device including the backside MOMCAP of FIG. 3H according to some embodiments. For simplicity of illustration, FIG. 3I only shows some elements of the integrated circuit device 100a. To help illustrate example embodiments of the present disclosure, the lines B-B′, C-C′, and D-D′ corresponding to the cross-sectional views of FIG. 3C, FIG. 3D, and FIG. 3E, respectively, are shown in the plan view of FIG. 3I. Like reference numerals refer to like elements. For simplicity of description, repeated descriptions of like elements described above may be omitted.

As shown in FIG. 3I, the integrated circuit device 100a may include the plurality of unit cells 100a-1 to 100a-4. For example, the first unit cell 100a-1 of the integrated circuit device 100a may correspond to the plan view of the integrated circuit device 100a shown in FIG. 3B. Although FIG. 3I illustrates four unit cells 100a-1 to 100a-4, the present disclosure is not limited thereto. In other embodiments, the integrated circuit device 100a may include more than four unit cells or less than four unit cells.

As shown in FIG. 3I, the interdigitated upper backside fingers 180a-1, 180b-1 may extend (e.g., may longitudinally extend) in the first direction X, and the gate structures 170′ (and the upper and lower gate structures 170a′ and 170b′ included therein) may extend (e.g., may longitudinally extend) in the second direction Y. For example, a longest dimension of the interdigitated upper backside fingers 180a-1, 180b-1 may be in the first direction X, and a longest dimension of the gate structures 170′ (and the upper and lower gate structures 170a′ and 170b′ included therein) may be in the second direction Y, although embodiments of the present disclosure are not limited thereto. For example, the interdigitated upper backside fingers 180a-1, 180b-1 may extend perpendicular to the gate structures 170′ (and the upper and lower gate structures 170a′ and 170b′ included therein). The gate structures 170′ (and the upper and lower gate structures 170a′ and 170b′ included therein) may overlap the interdigitated upper backside fingers 180a-1, 180b-1 in the third direction Z. The first, second, third, and fourth upper conductive plugs 158a, 158b, 156a, and 156b and the lower and upper gate contacts 142 and 148 may also overlap the interdigitated upper backside fingers 180a-1, 180b-1 in the third direction Z. For example, the first and second upper conductive plugs 158a, 158b and the lower gate contacts 142 (shown by a dotted line box in FIG. 3I) may overlap ones of the first upper backside fingers 180a-1 in the third direction Z, and the third and fourth upper conductive plugs 156a, 156b and the upper gate contacts 148 may overlap ones of the second upper backside fingers 180b-1 in the third direction Z.

FIG. 3J is a schematic circuit diagram of the MOSCAP of FIGS. 3A-E according to some embodiments. FIG. 3K is a schematic circuit diagram of the integrated circuit device of FIGS. 3A-E according to some embodiments.

As shown in FIG. 3J, the MOSCAP 102 includes the lower semiconductor device Sb and the upper semiconductor device Sa. The lower gate structure 170b′ of the lower semiconductor device Sb may be electrically connected (i.e., electrically shorted) to both of the pair of upper source/drain regions 150 of the upper semiconductor device Sa. The lower gate structure 170b′ may be configured to receive a first voltage. In some embodiments, the first voltage is a drain voltage Vdd as shown in FIG. 3J, but the present disclosure is not limited thereto. The pair of lower source/drain regions 140 of the lower semiconductor device Sb may be configured to receive a second voltage. In some embodiments, the second voltage is a source voltage Vss as shown in FIG. 3J, but the present disclosure is not limited thereto. For example, as shown in FIG. 3J, the source voltage Vss may have a value of zero volts (0 V), although embodiments of the present disclosure are not limited thereto. The gate-to-source voltage Vgs applied to the lower semiconductor device Sb may thus correspond to the first voltage (i.e., +Vdd). The second voltage is different from the first voltage.

The upper gate structure 170a′ of the upper semiconductor device Sa may be electrically connected (i.e., electrically shorted) to both of the pair of lower source/drain regions 140 of the lower semiconductor device Sb. The upper gate structure 170a′ may be configured to receive the second voltage (e.g., Vss). As shown in FIG. 3J, the source voltage Vss may have a value of zero volts (0 V), although embodiments of the present disclosure are not limited thereto. The pair of upper source/drain regions 150 of the upper semiconductor device Sa are configured to receive the first voltage (e.g., Vdd). The gate-to-source voltage Vgs applied to the upper semiconductor device Sa may thus correspond to the first voltage with reversed polarity (i.e., −Vdd). In other words, the gate-to-source voltage Vgs applied to the upper semiconductor device Sa may thus correspond to the negative version of the first voltage (i.e., −Vdd).

As shown in FIG. 3K, the MOSCAP 102 is electrically connected between the frontside MOMCAP 104 and the backside MOMCAP 106. In other words, the MOSCAP 102, the frontside MOMCAP 104, and the backside MOMCAP 106 may be electrically connected to each other. For example, the MOSCAP 102 may be connected in electrical parallel with the frontside MOMCAP 104 and the backside MOMCAP 106, although embodiments of the present disclosure are not limited thereto. For example, the first voltage (e.g., a drain voltage Vdd) and the second voltage (e.g., a source voltage Vss) may be electrically connected to a first node 103 and a second node 105, respectively. In some embodiments, the first node 103 and the second node 105 may correspond to an input path and an output path, respectively, of the MOSCAP 102, frontside MOMCAP 104, and backside MOMCAP 106, but the present disclosure is not limited thereto. Although FIGS. 3J and 3K illustrate that the upper semiconductor device Sa is a p-type device, and the lower semiconductor device Sb is an n-type device, embodiments of the present disclosure are not limited thereto. In other embodiments, the upper semiconductor device Sa may be an n-type device, and the lower semiconductor device Sb may be a p-type device. In this case, the first voltage (e.g., Vdd) and the second voltage (e.g., Vss) shown in FIGS. 3J and 3K may be reversed. That is, the upper gate structure 170a′ and the pair of lower source/drain regions 140 may be configured to receive the first voltage (e.g., Vdd), and the lower gate structure 170b′ and the pair of upper source/drain regions 150 may be configured to receive the second voltage (e.g., Vss).

Referring back to FIGS. 3A-E, the integrated circuit device 100a may include at least three capacitors: the MOSCAP 102, the frontside MOMCAP 104 and the backside MOMCAP 106. The MOSCAP 102, the frontside MOMCAP 104 and the backside MOMCAP 106 may be provided by modifying the existing architecture used to form three-dimensional (3D) stacked transistors (e.g., see the transistor stack 101 of FIGS. 2A-D), and thus the MOSCAP 102, the frontside MOMCAP 104 and the backside MOMCAP 106 may not disadvantageously impact the integration density of the integrated circuit device 100a and may be seamlessly implemented in the integrated circuit device 100a. As a result, the integrated circuit device 100a may include a plurality of high-density capacitors. These capacitors, for example, may function as decoupling capacitors. For example, an integrated circuit device according to some embodiments of the present disclosure may include the MOSCAP 102, the frontside MOMCAP 104, and the backside MOMCAP 106, along with the upper and lower transistors Ta, Tb of the transistor stack 101 (see FIGS. 2A-D). For example, the MOSCAP 102, the frontside MOMCAP 104, and the backside MOMCAP 106 may operate in conjunction with the upper and lower transistors Ta, Tb of the transistor stack 101 to help provide a stable voltage supply and/or filter out noise within the integrated circuit device, thereby improving the performance and reliability of the integrated circuit device.

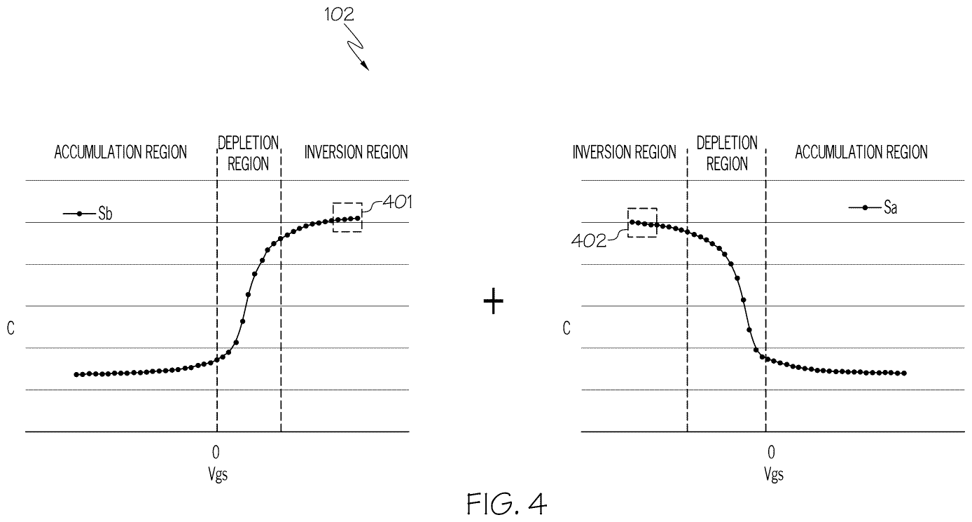

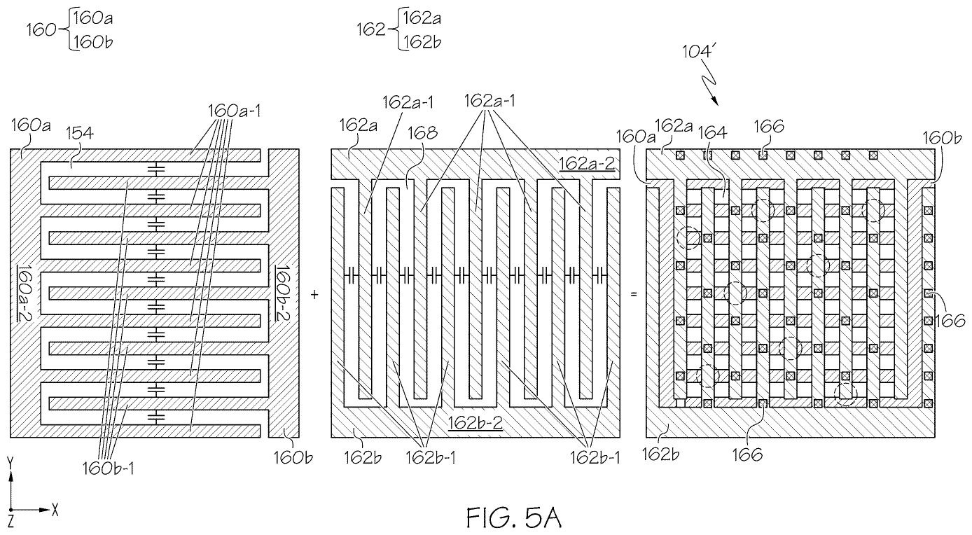

FIG. 4 is a graph illustrating a C-V curve of the MOSCAP of FIGS. 3A-E according to some embodiments. In particular, FIG. 4 illustrates the relationship between the capacitanceI) of the MOSCAP 102 and a gate-to-source voltage (Vgs) applied to the MOSCAP 102. A vertical axis in FIG. 4 corresponds to the capacitaI (C) of the MOSCAP 102, and a horizontal axis in FIG. 4 corresponds to the gate-to-source voltage (Vgs) applied to the MOSCAP 102.

As shown in FIG. 4, the lower semiconductor device Sb and the upper semiconductor device Sa are configured to provide the MOSCAP 102. The lower semiconductor device Sb may operate in an accumulation region, a depletion region, or an inversion region based on the gate-to-source voltage (Vgs) applied to the lower semiconductor device Sb. Likewise, the upper semiconductor device Sa may operate in an accumulation region, a depletion region, or an inversion region based on the gate-to-source voltage (Vgs) applied to the upper semiconductor device Sa.

Referring to FIGS. 3J and 4, the gate-to-source voltage (Vgs) of the lower semiconductor device Sb is a function of the first voltage (e.g., Vdd) applied to the lower gate structure 170b′ of the lower semiconductor device Sb, and the second voltage (e.g., Vss) applied to the pair of lower source/drain regions 140 of the lower semiconductor device Sb. For example, the gate-to-source voltage (Vgs) of the lower semiconductor device Sb corresponds to the voltage difference between the first voltage and the second voltage. The capacitance value of the lower semiconductor device Sb may therefore vary based on the first and second voltages. The gate-to-source voltage (Vgs) of the upper semiconductor device Sa is a function of the second voltage (e.g., Vss) applied to the upper gate structure 170a′ of the upper semiconductor device Sa, and the first voltage (e.g., Vdd) applied to the pair of upper source/drain regions 150 of the upper semiconductor device Sa. For example, the gate-to-source voltage (Vgs) of the upper semiconductor device Sa corresponds to the voltage difference between the second voltage and the first voltage. The capacitance value of the upper semiconductor device Sa may therefore vary based on the first and second voltages.

By electrically connecting the lower gate structure 170b′ of the lower semiconductor device Sb to both of the pair of upper source/drain regions 150 of the upper semiconductor device Sa, and electrically connecting the upper gate structure 170a′ of the upper semiconductor device Sa to both of the pair of lower source/drain regions 140 of the lower semiconductor device Sb, the MOSCAP 102 may be configured to have a maximum capacitance value when both the lower semiconductor device Sb and the upper semiconductor device Sa operate in the inversion region. As used herein, “a maximum capacitance value of the MOSCAP” (or similar language) refers to the highest capacitance that the MOSCAP 102 is configured to provide during normal operation of the integrated circuit device 100a. Further, both the lower semiconductor device Sb and the upper semiconductor device Sa may be configured to simultaneously operate in the inversion region by electrically separating (i.e., electrically isolating) the lower gate structure 170b′ of the lower semiconductor device Sb from the upper gate structure 170a′ of the upper semiconductor device Sa.

As shown in FIGS. 3J and 4, when the gate-to-source voltage (Vgs) applied to the lower semiconductor device Sb causes the lower semiconductor device Sb to operate in the inversion region, the lower semiconductor device Sb may have a maximum capacitance value 401 (shown by a dashed box in FIG. 4). In other words, the lower semiconductor device Sb may have (i.e., may exhibit) the maximum capacitance value 401 when the first and second voltages (e.g., Vdd and Vss) cause the lower semiconductor device Sb to operate in the inversion region. A capacitance value of the lower semiconductor device Sb may decrease when the first and second voltages cause the lower semiconductor device Sb to operate in the depletion region, and may further decrease when the first and second voltages cause the lower semiconductor device Sb to operate in the accumulation region. Accordingly, the capacitance value of the lower semiconductor device Sb may vary based on the gate-to-source voltage (Vgs) applied to the lower semiconductor device Sb.

Still referring to FIGS. 3J and 4, when the gate-to-source voltage (Vgs) applied to the upper semiconductor device Sa causes the upper semiconductor device Sa to operate in the inversion region, the upper semiconductor device Sa may have a maximum capacitance value 402 (shown by a dashed box in FIG. 4). In other words, the upper semiconductor device Sa may have (i.e., may exhibit) the maximum capacitance value 402 when the first and second voltages (e.g., Vdd and Vss) cause the upper semiconductor device Sa to operate in the inversion region. A capacitance value of the upper semiconductor device Sa may decrease when the first and second voltages cause the upper semiconductor device Sa to operate in the depletion region, and may further decrease when the first and second voltages cause the upper semiconductor device Sa to operate in the accumulation region. Accordingly, the capacitance value of the upper semiconductor device Sa may vary based on the gate-to-source voltage (Vgs) applied to the upper semiconductor device Sa.

As described above, the MOSCAP 102 is configured to have a maximum capacitance value (e.g., 401 +402) when the first voltage (e.g., Vdd) and the second voltage (e.g., Vss) cause the lower semiconductor device Sb and the upper semiconductor device Sa to both operate in the inversion region. Unlike the MOSCAP 3 of the conventional integrated circuit device 1 (see FIG. 1), where the MOSCAP 3 may be configured to have a maximum capacitance value when the first MOSCAP 4 and the second MOSCAP 5 both operate in the accumulation region, the MOSCAP 102 according to embodiments of the present disclosure may have a maximum capacitance value when the lower semiconductor device Sb and the upper semiconductor device Sa both operate in the inversion region. The capacitance value may be further increased by electrically connecting the MOSCAP 102 to both the frontside MOMCAP 104 and the backside MOMCAP 106, as described above.

Although FIGS. 3J and 4 illustrate that the upper semiconductor device Sa is a p-type device, and the lower semiconductor device Sb is an n-type device, embodiments of the present disclosure are not limited thereto. In other embodiments, the upper semiconductor device Sa may be an n-type device, and the lower semiconductor device Sb may be a p-type device. In this case, the C-V curves for the upper and lower semiconductor devices Sa, Sb may be reversed from that shown in FIG. 4.

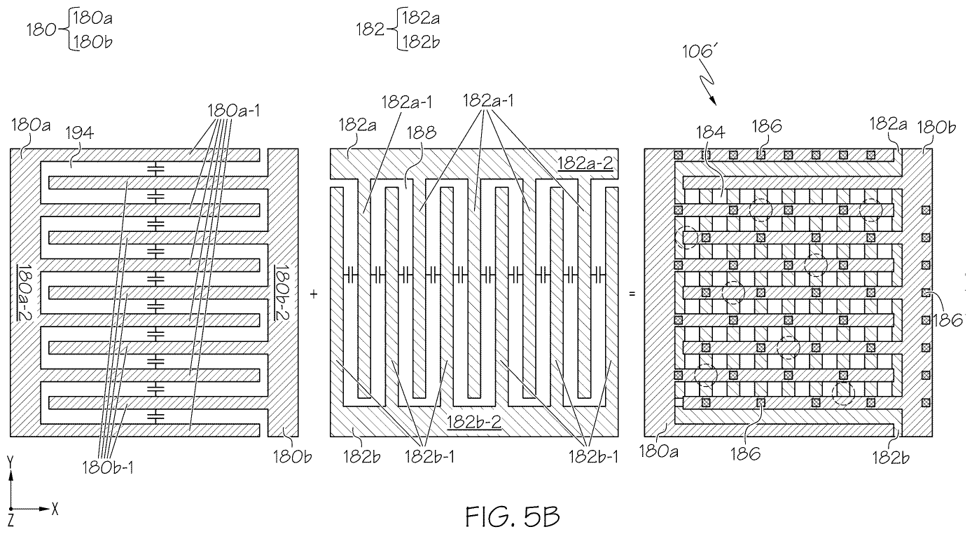

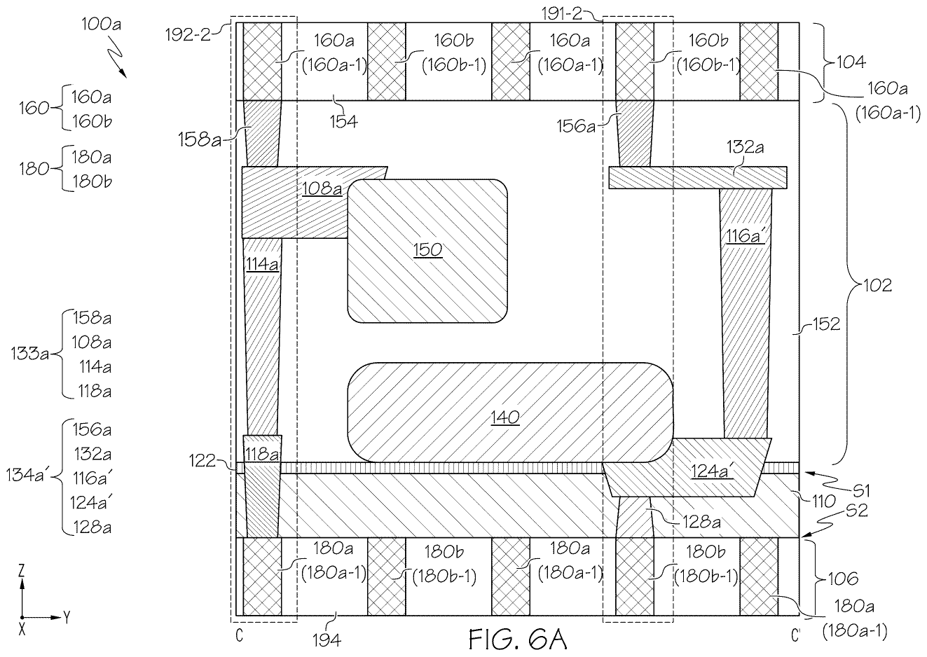

FIG. 5A is a schematic plan view of a frontside MOMCAP according to some further embodiments. FIG. 5B is a schematic plan view of a backside MOMCAP according to some further embodiments. Like reference numerals refer to like elements. For simplicity of description, repeated descriptions of like elements described above may be omitted.

Referring to FIG. 5A, the frontside MOMCAP 104′ may include the lower frontside metallization pattern 160. The frontside MOMCAP 104′ may further include an upper frontside metallization pattern 162 on (e.g., stacked on) the lower frontside metallization pattern 160 (e.g., in the third direction Z), and a frontside insulating layer 164 between (e.g., in the third direction Z) the lower frontside metallization pattern 160 and the upper frontside metallization pattern 162. The upper frontside metallization pattern 162 may include a first upper frontside metallization layer 162a and a second upper frontside metallization layer 162b. The upper frontside metallization pattern 162 may include a metal layer or material including, for example, W, Al, Cu, Mo, Co and/or Ru. The frontside insulating layer 164 may include insulating material(s) (e.g., silicon oxide, silicon oxynitride, silicon nitride, silicon carbonitride and/or a low-k material). Although the frontside insulating layer 164 is illustrated as a single layer, in some embodiments, the frontside insulating layer 164 may include multiple layers.

The frontside MOMCAP 104′ may further include a fourth insulating layer 168 that extends between the first upper frontside metallization layer 162a and the second upper frontside metallization layer 162b. The fourth insulating layer 168 may include insulating material(s) (e.g., silicon oxide, silicon oxynitride, silicon nitride, silicon carbonitride and/or a low-k material). Although the fourth insulating layer 168 is illustrated as a single layer, in some embodiments, the fourth insulating layer 168 may include multiple layers. For example, the fourth insulating layer 168 may insulate (i.e., isolate) the first upper frontside metallization layer 162a from the second upper frontside metallization layer 162b. In some embodiments, the first upper frontside metallization layer 162a may be configured to receive a first voltage (e.g., a drain voltage Vdd), and the second upper frontside metallization layer 162b may be configured to receive a second voltage (e.g., a source voltage Vss).

The first upper frontside metallization layer 162a may include a plurality of first upper frontside fingers 162a-1 and a first upper frontside conductive plate 162a-2. The first upper frontside fingers 162a-1 may extend (e.g., may longitudinally extend) in the second direction Y from the first upper frontside conductive plate 162a-2. For example, the first upper frontside conductive plate 162a-2 may act as a common electrical path for the first upper frontside fingers 162a-1, and may share the first voltage with the first upper frontside fingers 162a-1. In some embodiments, a longest dimension of the first upper frontside fingers 162a-1 may be in the second direction Y.

The second upper frontside metallization layer 162b may include a plurality of second upper frontside fingers 162b-1 and a second upper frontside conductive plate 162b-2. The second upper frontside fingers 162b-1 may extend (e.g., may longitudinally extend) in the second direction Y (e.g., opposite the first upper frontside fingers 162a-1) from the second upper frontside conductive plate 162b-2. For example, the second upper frontside conductive plate 162b-2 may act as a common electrical path for the second upper frontside fingers 162b-1, and may share the second voltage with the second upper frontside fingers 162b-1. In some embodiments, a longest dimension of the second upper frontside fingers 162b-1 may be in the second direction Y.

The first upper frontside fingers 162a-1 and the second upper frontside fingers 162b-1 may be interdigitated (e.g., may resemble an interlocking structure, such as the fingers of clasped hands), and thus the first upper frontside fingers 162a-1 and the second upper frontside fingers 162b-1 may be collectively referred to as interdigitated upper frontside fingers 162a-1, 162b-1. As shown in FIG. 5A, the fourth insulating layer 168 extends between adjacent ones If the interdigitated upper frontside fingers 162a-1, 162b-1, and a capacitance (shown by a capacitor symbol in FIG. 5A) may thus be formed between the adjacent ones of the interdigitated upper frontside fingers 162a-1, 162b-1 (e.g., in the first direction X). The interdigitated upper frontside fingers 162a-1, 162b-1 may extend in the second direction Y and may be spaced apart from each other in the first direction X. The first upper frontside fingers 162a-1 and the second upper frontside fingers 162b-1 may not be galvanically coupled to each other (e.g., may not have a direct electrical connection therebetween) and instead may only be capacitively coupled to each other. In other words, the first upper frontside metallization layer 162a and the second upper frontside metallization layer 162b may not be galvanically coupled to each other (e.g., may not have a direct electrical connection therebetween) and instead may only be capacitively coupled to each other. Although FIG. 5A illustrates eleven interdigitated upper frontside fingers 162a-1, 162b-1, the present disclosure is not limited thereto. In other embodiments, the frontside MOMCAP 104′ may include more than eleven interdigitated upper frontside fingers 162a-1, 162b-1 or less than eleven interdigitated upper frontside fingers 162a-1, 162b-1.

In some embodiments, each of the interdigitated upper frontside fingers 162a-1, 162b-1 may have a width in the first direction X that is less than 100 nanometers (nm). In some embodiments, adjacent ones of the interdigitated upper frontside fingers 162a-1, 162b-1 (e.g., a respective one of the first upper frontside fingers 162a-1 that is adjacent to a respective one of the second upper frontside fingers 162b-1) may be spaced apart from each other by less than 100 nanometers (nm) in the first direction X. In other words, a distance in the first direction X between adjacent ones of the interdigitated upper frontside fingers 162a-1, 162b-1 may be less than 100 nanometers (nm).

Frontside vias 166 may be provided in the frontside insulating layer 164. The frontside vias 166 may extend in the frontside insulating layer 164 (e.g., in the third direction Z) between the lower frontside metallization pattern 160 and the upper frontside metallization pattern 162. First ones of the frontside vias 166 may extend between the first lower frontside metallization layer 160a and the first upper frontside metallization layer 162a, and may electrically connect the first lower frontside metallization layer 160a to the first upper frontside metallization layer 162a. In other words, the first ones of the frontside vias 166 may galvanically couple (e.g., may provide a direct electrical connection between) the first lower frontside metallization layer 160a and the first upper frontside metallization layer 162a. The first upper frontside metallization layer 162a may thus be electrically connected to the first lower frontside metallization layer 160a. Second ones of the frontside vias 166 may extend between the second lower frontside metallization layer 160b and the second upper frontside metallization layer 162b, and may electrically connect the second lower frontside metallization layer 160b to the second upper frontside metallization layer 162b. In other words, the second ones of the frontside vias 166 may galvanically couple (e.g., may provide a direct electrical connection between) the second lower frontside metallization layer 160b and the second upper frontside metallization layer 162b. The second upper frontside metallization layer 162b may thus be electrically connected to the second lower frontside metallization layer 160b.

The first upper frontside metallization layer 162a and the second lower frontside metallization layer 160b may not be galvanically coupled to each other (e.g., may not have a direct electrical connection therebetween) and may be electrically separated from each other by the frontside insulating layer 164. Likewise, the second upper frontside metallization layer 162b and the first lower frontside metallization layer 160a may not be galvanically coupled to each other (e.g., may not have a direct electrical connection therebetween) and may be electrically separated from each other by the frontside insulating layer 164.

As shown in FIG. 5A, the interdigitated lower frontside fingers 160a-1, 160b-1 may extend in the first direction X, while the interdigitated upper frontside fingers 162a-1, 162b-1 may extend in the second direction Y. For example, the interdigitated lower frontside fingers 160a-1, 160b-1 may extend perpendicular to the interdigitated upper frontside fingers 162a-1, 162b-1. The interdigitated upper frontside fingers 162a-1, 162b-1 may extend on the interdigitated lower frontside fingers 160a-1, 160b-1 and may overlap the interdigitated lower frontside fingers 160a-1, 160b-1 (e.g., in the third direction Z). A capacitance (shown by dashed circles in FIG. 5A) may thus be formed between the interdigitated lower frontside fingers 160a-1, 160b-1 and the interdigitated upper frontside fingers 162a-1, 162b-1. For example, a capacitance may be formed where the first upper frontside fingers 162a-1 overlap the second lower frontside fingers 160b-1 (e.g., with the frontside insulating layer 164 therebetween), since the first upper frontside metallization layer 162a and the second lower frontside metallization layer 160b are not galvanically coupled to each other. Likewise, a capacitance may be formed where the second upper frontside fingers 162b-1 overlap the first lower frontside fingers 160a-1 (e.g., with the frontside insulating layer 164 therebetween), since the second upper frontside metallization layer 162b and the first lower frontside metallization layer 160a are not galvanically coupled to each other.

The dashed circles are provided in FIG. 5A to help illustrate example embodiments of the present disclosure. For simplicity of illustration, the dashed circles in FIG. 5A only identify some of the capacitance that may be formed between the interdigitated lower frontside fingers 160a-1, 160b-1 and the interdigitated upper frontside fingers 162a-1, 162b-1. It will be understood that additional capacitance may exist between the interdigitated lower frontside fingers 160a-1, 160b-1 and the interdigitated upper frontside fingers 162a-1, 162b-1 that is not identified by the dashed circles in FIG. 5A.

The upper frontside metallization pattern 162 of the frontside MOMCAP 104′ may increase the capacitance density (i.e., may increase the amount of capacitance per unit area) of the frontside MOMCAP 104′. For example, the frontside MOMCAP 104′ may have capacitance between: (i) adjacent ones of the interdigitated lower frontside fingers 160a-1, 160b-1, (ii) adjacent ones of the interdigitated upper frontside fingers 162a-1, 162b-1, and (iii) the interdigitated lower frontside fingers 160a-1, 160b-1 and the interdigitated upper frontside fingers 162a-1, 162b-1. The capacitance density of the frontside MOMCAP 104′ may also be increased by configuring the interdigitated lower frontside fingers 160a-1, 160b-1 to extend in the first direction X while configuring the interdigitated upper frontside fingers 162a-1, 162b-1 to extend in the second direction Y, to thereby increase the overlap that may occur between the interdigitated upper frontside fingers 162a-1, 162b-1 and the interdigitated lower frontside fingers 160a-1, 160b-1.

As described above, the frontside MOMCAP 104′ may include the upper frontside metallization pattern 162 on (e.g., stacked on) the lower frontside metallization pattern 160, with the frontside insulating layer 164 therebetween. For example, the lower frontside metallization pattern 160 may be between, in the third direction Z, the substrate 110 (e.g., see FIGS. 3A-E) and the upper frontside metallization pattern 162. Said another way, the lower frontside metallization pattern 160 may be between, in the third direction Z, the MOSCAP 102 (e.g., see FIGS. 3A-E) and the upper frontside metallization pattern 162. It will be understood that, in some embodiments, the frontside MOMCAP 104 described above (e.g., see FIGS. 3A-E) may be replaced with the frontside MOMCAP 104′. That is, the integrated circuit device 100a described above is not limited to including the frontside MOMCAP 104 and instead may include the frontside MOMCAP 104′. Although FIG. 5A illustrates that the frontside MOMCAP 104′ includes two metallization patterns (i.e., the upper frontside metallization pattern 162 and the lower frontside metallization pattern 160), embodiments of the present disclosure are not limited thereto. In some other embodiments, the frontside MOMCAP 104′ may include three, four, five, six, or more metallization patterns stacked on one another, with insulating layers (i.e., dielectric layers) respectively provided between each metallization pattern. For example, in some other embodiments, the frontside MOMCAP 104′ may include at least four metallization patterns stacked on one another (e.g., in the third direction Z), with the interdigitated fingers of successive metallization patterns alternating between extending in the first direction X and the second direction Y. In other words, in some other embodiments, the frontside MOMCAP 104′ may include the lower frontside metallization pattern 160 as a lowermost metallization pattern, the upper frontside metallization pattern 162 on (e.g., stacked on) the lower frontside metallization pattern 160 (e.g., in the third direction Z), another lower frontside metallization pattern 160 on (e.g., stacked on) the upper frontside metallization pattern 162 (e.g., in the third direction Z), and another upper frontside metallization pattern 162 on (e.g., stacked on) the another lower frontside metallization pattern 160 (e.g., in the third direction Z).

Referring to FIG. 5B, the backside MOMCAP 106′ may include the upper backside metallization pattern 180. The backside MOMCAP 106′ may further include a lower backside metallization pattern 182 on a lower surface of the upper backside metallization pattern 180 (e.g., in the third direction Z), and a backside insulating layer 184 between (e.g., in the third direction Z) the upper backside metallization pattern 180 and the lower backside metallization pattern 182. For example, the upper backside metallization pattern 180 may be on (e.g., may be stacked on) the lower backside metallization pattern 182 (e.g., in the third direction Z), with the backside insulating layer 184 therebetween. The lower backside metallization pattern 182 may include a first lower backside metallization layer 182a and a second lower backside metallization layer 182b. The lower backside metallization pattern 182 may include a metal layer or material including, for example, W, Al, Cu, Mo, Co and/or Ru. The backside insulating layer 184 may include insulating material(s) (e.g., silicon oxide, silicon oxynitride, silicon nitride, silicon carbonitride and/or a low-k material). Although the backside insulating layer 184 is illustrated as a single layer, in some embodiments, the backside insulating layer 184 may include multiple layers.

The backside MOMCAP 106′ may further include a fifth insulating layer 188 that extends between the first lower backside metallization layer 182a and the second lower backside metallization layer 182b. The fifth insulating layer 188 may include insulating material(s) (e.g., silicon oxide, silicon oxynitride, silicon nitride, silicon carbonitride and/or a low-k material). Although the fifth insulating layer 188 is illustrated as a single layer, in some embodiments, the fifth insulating layer 188 may include multiple layers. For example, the fifth insulating layer 188 may insulate (i.e., isolate) the first lower backside metallization layer 182a from the second lower backside metallization layer 182b. In some embodiments, the first lower backside metallization layer 182a may be configured to receive a first voltage (e.g., a drain voltage Vdd), and the second lower backside metallization layer 182b may be configured to receive a second voltage (e.g., a source voltage Vss).

The first lower backside metallization layer 182a may include a plurality of first lower backside fingers 182a-1 and a first lower backside conductive plate 182a-2. The first lower backside fingers 182a-1 may extend (e.g., may longitudinally extend) in the second direction Y from the first lower backside conductive plate 182a-2. For example, the first lower backside conductive plate 182a-2 may act as a common electrical path for the first lower backside fingers 182a-1, and may share the first voltage with the first lower backside fingers 182a-1. In some embodiments, a longest dimension of the first lower backside fingers 182a-1 may be in the second direction Y.

The second lower backside metallization layer 182b may include a plurality of second lower backside fingers 182b-1 and a second lower backside conductive plate 182b-2. The second lower backside fingers 182b-1 may extend (e.g., may longitudinally extend) in the second direction Y (e.g., opposite the first lower backside fingers 182a-1) from the second lower backside conductive plate 182b-2. For example, the second lower backside conductive plate 182b-2 may act as a common electrical path for the second lower backside fingers 182b-1, and may share the second voltage with the second lower backside fingers 182b-1. In some embodiments, a longest dimension of the second lower backside fingers 182b-1 may be in the second direction Y.

The first lower backside fingers 182a-1 and the second lower backside fingers 182b-1 may be interdigitated (e.g., may resemble an interlocking structure, such as the fingers of clasped hands), and thus the first lower backside fingers 182a-1 and the second lower backside fingers 182b-1 may be collectively referred to as interdigitated lower backside fingers 182a-1, 182b-1. As shown in FIG. 5B, the fifth insulating layer 188 extends between adjacent ones of the interdigitated lower backside fingers 182a-1, 182b-1, and a capacitance (shown by a capacitor symbol in FIG. 5B) may thus be formed between the adjacent ones of the interdigitated lower backside fingers 182a-1, 182b-1 (e.g., in the first direction X). The interdigitated lower backside fingers 182a-1, 182b-1 may extend in the second direction Y and may be spaced apart from each other in the first direction X. The first lower backside fingers 182a-1 and the second lower backside fingers 182b-1 may not be galvanically coupled to each other (e.g., may not have a direct electrical connection therebetween) and instead may only be capacitively coupled to each other. In other words, the first lower backside metallization layer 182a and the second lower backside metallization layer 182b may not be galvanically coupled to each other (e.g., may not have a direct electrical connection therebetween) and instead may only be capacitively coupled to each other. Although FIG. 5B illustrates eleven interdigitated lower backside fingers 182a-1, 182b-1, the present disclosure is not limited thereto. In other embodiments, the backside MOMCAP 106′ may include more than eleven interdigitated lower backside fingers 182a-1, 182b-1 or less than eleven interdigitated lower backside fingers 182a-1, 182b-1.

In some embodiments, each of the interdigitated lower backside fingers 182a-1, 182b-1 may have a width in the first direction X that is less than 100 nanometers (nm). In some embodiments, adjacent ones of the interdigitated lower backside fingers 182a-1, 182b-1 (e.g., a respective one of the first lower backside fingers 182a-1 that is adjacent to a respective one of the second lower backside fingers 182b-1) may be spaced apart from each other by less than 100 nanometers (nm) in the first direction X. In other words, a distance in the first direction X between adjacent ones of the interdigitated lower backside fingers 182a-1, 182b-1 may be less than 100 nanometers (nm).

Backside vias 186 may be provided in the backside insulating layer 184. The backside vias 186 may extend in the backside insulating layer 184 (e.g., in the third direction Z) between the upper backside metallization pattern 180 and the lower backside metallization pattern 182. First ones of the backside vias 186 may extend between the first upper backside metallization layer 180a and the first lower backside metallization layer 182a, and may electrically connect the first upper backside metallization layer 180a to the first lower backside metallization layer 182a. In other words, the first ones of the backside vias 186 may galvanically couple (e.g., may provide a direct electrical connection between) the first upper backside metallization layer 180a and the first lower backside metallization layer 182a. The first lower backside metallization layer 182a may thus be electrically connected to the first upper backside metallization layer 180a. Second ones of the backside vias 186 may extend between the second upper backside metallization layer 180b and the second lower backside metallization layer 182b, and may electrically connect the second upper backside metallization layer 180b to the second lower backside metallization layer 182b. In other words, the second ones of the backside vias 186 may galvanically couple (e.g., may provide a direct electrical connection between) the second upper backside metallization layer 180b and the second lower backside metallization layer 182b. The second lower backside metallization layer 182b may thus be electrically connected to the second upper backside metallization layer 180b.

The first lower backside metallization layer 182a and the second upper backside metallization layer 180b may not be galvanically coupled to each other (e.g., may not have a direct electrical connection therebetween) and may be electrically separated from each other by the backside insulating layer 184. Likewise, the second lower backside metallization layer 182b and the first upper backside metallization layer 180a may not be galvanically coupled to each other (e.g., may not have a direct electrical connection therebetween) and may be electrically separated from each other by the backside insulating layer 184.

As shown in FIG. 5B, the interdigitated upper backside fingers 180a-1, 180b-1 may extend in the first direction X, while the interdigitated lower backside fingers 182a-1, 182b-1 may extend in the second direction Y. For example, the interdigitated upper backside fingers 180a-1, 180b-1 may extend perpendicular to the interdigitated lower backside fingers 182a-1, 182b-1. The interdigitated upper backside fingers 180a-1, 180b-1 may extend on the interdigitated lower backside fingers 182a-1, 182b-1 and may overlap the interdigitated lower backside fingers 182a-1, 182b-1 (e.g., in the third direction Z). A capacitance (shown by dashed circles in FIG. 5B) may thus be formed between the interdigitated upper backside fingers 180a-1, 180b-1 and the interdigitated lower backside fingers 182a-1, 182b-1. For example, a capacitance may be formed where the first upper backside fingers 180a-1 overlap the second lower backside fingers 182b-1 (e.g., with the backside insulating layer 184 therebetween), since the second lower backside metallization layer 182b and the first upper backside metallization layer 180a are not galvanically coupled to each other. Likewise, a capacitance may be formed where the second upper backside fingers 180b-1 overlap the first lower backside fingers 182a-1 (e.g., with the backside insulating layer 184 therebetween), since the first lower backside metallization layer 182a and the second upper backside metallization layer 180b are not galvanically coupled to each other.

The dashed circles are provided in FIG. 5B to help illustrate example embodiments of the present disclosure. For simplicity of illustration, the dashed circles in FIG. 5B only identify some of the capacitance that may be formed between the interdigitated upper backside fingers 180a-1, 180b-1 and the interdigitated lower backside fingers 182a-1, 182b-1. It will be understood that additional capacitance may exist between the interdigitated upper backside fingers 180a-1, 180b-1 and the interdigitated lower backside fingers 182a-1, 182b-1 that is not identified by the dashed circles in FIG. 5B.

The lower backside metallization pattern 182 of the backside MOMCAP 106′ may increase the capacitance density (i.e., may increase the amount of capacitance per unit area) of the backside MOMCAP 106'. For example, the backside MOMCAP 106′ may have capacitance between: (i) adjacent ones of the interdigitated upper backside fingers 180a-1, 180b-1, (ii) adjacent ones of the interdigitated lower backside fingers 182a-1, 182b-1, and (iii) the interdigitated upper backside fingers 180a-1, 180b-1 and the interdigitated lower backside fingers 182a-1, 182b-1. The capacitance density of the backside MOMCAP 106′ may also be increased by configuring the interdigitated upper backside fingers 180a-1, 180b-1 to extend in the first direction X while configuring the interdigitated lower backside fingers 182a-1, 182b-1 to extend in the second direction Y, to thereby increase the overlap that may occur between the interdigitated upper backside fingers 180a-1, 180b-1 and the interdigitated lower backside fingers 182a-1, 182b-1.

As described above, the backside MOMCAP 106′ may include the upper backside metallization pattern 180 on (e.g., stacked on) the lower backside metallization pattern 182, with the backside insulating layer 184 therebetween. For example, the upper backside metallization pattern 180 may be between, in the third direction Z, the substrate 110 (e.g., see FIGS. 3A-E) and the lower backside metallization pattern 182. Said another way, the upper backside metallization pattern 180 may be between, in the third direction Z, the MOSCAP 102 (e.g., see FIGS. 3A-E) and the lower backside metallization pattern 182. It will be understood that, in some embodiments, the backside MOMCAP 106 described above (e.g., see FIGS. 3A-E) may be replaced with the backside MOMCAP 106′. That is, the integrated circuit device 100a described above is not limited to including the backside MOMCAP 106 and instead may include the backside MOMCAP 106′. Although FIG. 5B illustrates that the backside MOMCAP 106′ includes two metallization patterns (i.e., the upper backside metallization pattern 180 and the lower backside metallization pattern 182), embodiments of the present disclosure are not limited thereto. In some other embodiments, the backside MOMCAP 106′ may include three, four, five, six, or more metallization patterns stacked on one another, with insulating layers (i.e., dielectric layers) respectively provided between each metallization pattern. For example, in some other embodiments, the backside MOMCAP 106′ may include at least four metallization patterns stacked on one another (e.g., in the third direction Z), with the interdigitated fingers of successive metallization patterns alternating between extending in the first direction X and the second direction Y. In other words, in some other embodiments, the backside MOMCAP 106′ may include the upper backside metallization pattern 180 as an uppermost metallization pattern, the lower backside metallization pattern 182 on a lower surface of the upper backside metallization pattern 180 (e.g., in the third direction Z), another upper backside metallization pattern 180 on a lower surface of the lower backside metallization pattern 182 (e.g., in the third direction Z), and another lower backside metallization pattern 182 on a lower surface of the another upper backside metallization pattern 180 (e.g., in the third direction Z).

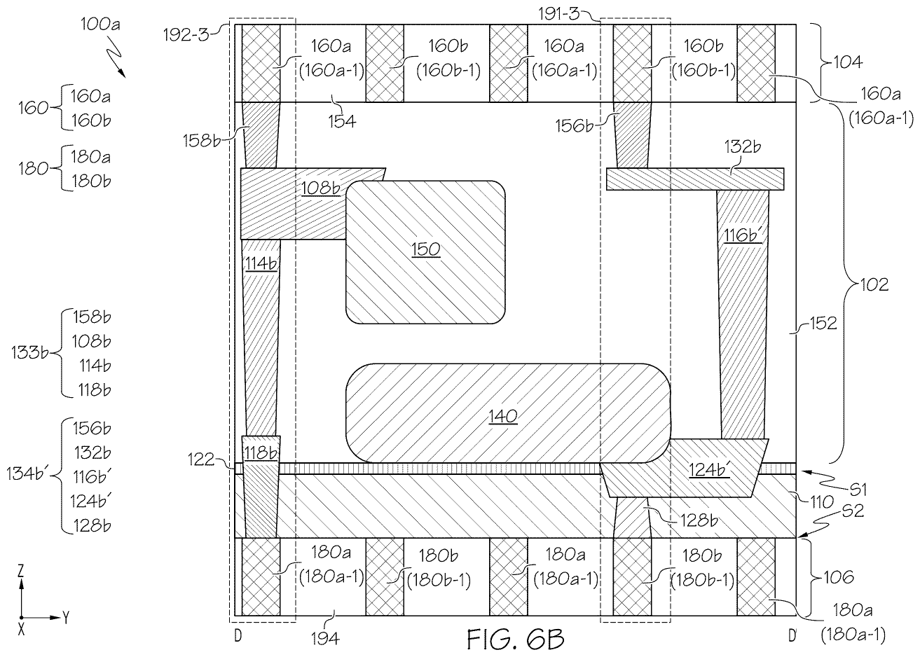

FIG. 6A is a schematic cross-sectional view taken along line C-C′ of FIG. 3B according to some further embodiments. FIG. 6B is a schematic cross-sectional view taken along line D-D′ of FIG. 3B according to some further embodiments. Like reference numerals refer to like elements. For simplicity of description, repeated descriptions of like elements described above may be omitted.

As shown in FIG. 6A, the first lower source/drain contact structure 134a′ may not include the third source/drain contact 112a (see FIG. 3D). For example, an upper surface of the first one of the pair of lower source/drain regions 140 may be free of contact with the first lower source/drain contact structure 134a′. The first lower source/drain contact structure 134a′ may include the third middle conductive plug 116a′, the fourth source/drain contact 124a′, and a third lower conductive plug 128a. The third lower conductive plug 128a may be electrically connected between the fourth source/drain contact 124a′ and the backside MOMCAP 106. For example, the third lower conductive plug 128a may be in contact with (e.g., may be in electrical contact with) the backside MOMCAP 106, according to some embodiments. The third middle conductive plug 116a′ may be electrically connected between the first conductive line 132a and the fourth source/drain contact 124a'. The fourth source/drain contact 124a′ may be in contact with (e.g., may be in electrical contact with) the first one of the pair of lower source/drain regions 140. For example, the fourth source/drain contact 124a′ may be on and in contact with a lower surface of the first one of the pair of lower source/drain regions 140. The third lower conductive plug 128a may include a metal layer or material including, for example, W, Al, Cu, Mo, Co and/or Ru.

A manufacturing process for the first lower source/drain contact structure 134a′ may be simplified and costs associated therewith may be reduced by only providing the fourth source/drain contact 124a′ on (and in contact with) a lower surface of the first one of the pair of lower source/drain regions 140, rather than providing both the third source/drain contact 112a (see FIG. 3D) on the upper surface of the first one of the pair of lower source/drain regions 140 and the fourth source/drain contact 124a′ on the lower surface of the first one of the pair of lower source/drain regions 140.

As shown in FIG. 6B, the second lower source/drain contact structure 134b′ may not include the fifth source/drain contact 112b (see FIG. 3E). For example, an upper surface of the second one of the pair of lower source/drain regions 140 may be free of contact with the second lower source/drain contact structure 134b′. The second lower source/drain contact structure 134b′ may include the fourth middle conductive plug 116b′, the sixth source/drain contact 124b′, and a fourth lower conductive plug 128b. The fourth lower conductive plug 128b may be electrically connected between the sixth source/drain contact 124b′ and the backside MOMCAP 106. For example, the fourth lower conductive plug 128b may be in contact with (e.g., may be in electrical contact with) the backside MOMCAP 106, according to some embodiments. The fourth middle conductive plug 116b′ may be electrically connected between the second conductive line 132b and the sixth source/drain contact 124b′. The sixth source/drain contact 124b′ may be in contact with (e.g., may be in electrical contact with) the second one of the pair of lower source/drain regions 140. For example, the sixth source/drain contact 124b′ may be on and in contact with a lower surface of the second one of the pair of lower source/drain regions 140. The fourth lower conductive plug 128b may include a metal layer or material including, for example, W, Al, Cu, Mo, Co and/or Ru.

A manufacturing process for the second lower source/drain contact structure 134b′ may be simplified and costs associated therewith may be reduced by only providing the sixth source/drain contact 124b′ on (and in contact with) a lower surface of the second one of the pair of lower source/drain regions 140, rather than providing both the fifth source/drain contact 112b (see FIG. 3E) on the upper surface of the second one of the pair of lower source/drain regions 140 and the sixth source/drain contact 124b′ on the lower surface of the second one of the pair of lower source/drain regions 140.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, example embodiments may be described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device, comprising:
a substrate; and
a metal-oxide-semiconductor capacitor (MOSCAP) on the substrate, the MOSCAP comprising:
a lower semiconductor device on the substrate, the lower semiconductor device comprising a pair of lower source/drain regions and a lower gate structure between the pair of lower source/drain regions; and
an upper semiconductor device on the lower semiconductor device, the upper semiconductor device comprising a pair of upper source/drain regions and an upper gate structure between the pair of upper source/drain regions,
wherein the lower gate structure is electrically connected to both of the pair of upper source/drain regions.

2. The integrated circuit device of claim 1, wherein the upper gate structure is electrically connected to both of the pair of lower source/drain regions.

3. The integrated circuit device of claim 1, wherein the MOSCAP further comprises an isolation region between the lower gate structure and the upper gate structure, and
wherein the lower gate structure is electrically separated from the upper gate structure by the isolation region.

4. The integrated circuit device of claim 1, wherein the lower gate structure is configured to receive a first voltage, and
wherein the upper gate structure is configured to receive a second voltage different from the first voltage.

5. The integrated circuit device of claim 1, wherein the lower semiconductor device further comprises a plurality of lower channel layers between the pair of lower source/drain regions, the lower channel layers spaced apart from each other in a direction perpendicular to an upper surface of the substrate, and
wherein the upper semiconductor device further comprises a plurality of upper channel layers between the pair of upper source/drain regions, the upper channel layers spaced apart from each other in the direction.

6. The integrated circuit device of claim 1, wherein the pair of lower source/drain regions have a first conductivity type, and
wherein the pair of upper source/drain regions have a second conductivity type different from the first conductivity type.

7. The integrated circuit device of claim 1, wherein the lower gate structure and the upper gate structure are configured to receive a first voltage and a second voltage, respectively, and
wherein the MOSCAP is configured to have a maximum capacitance value when the first and second voltages cause the lower semiconductor device and the upper semiconductor device to both operate in an inversion region.

8. An integrated circuit device, comprising:
a substrate;
a frontside metal-oxide-metal capacitor (MOMCAP) on a first surface of the substrate; and
a backside MOMCAP on a second surface of the substrate opposite the first surface, the backside MOMCAP electrically connected to the frontside MOMCAP.

9. The integrated circuit device of claim 8, wherein the backside MOMCAP comprises an upper backside metallization pattern that includes a plurality of interdigitated upper backside fingers, and
wherein the interdigitated upper backside fingers extend in a first direction parallel to the first surface of the substrate and are spaced apart from each other in a second direction intersecting the first direction.

10. The integrated circuit device of claim 9, further comprising a semiconductor device on the first surface of the substrate, the semiconductor device comprising a pair of source/drain regions and a gate structure between the pair of source/drain regions,
wherein the gate structure extends in the second direction and overlaps at least one of the interdigitated upper backside fingers in a third direction perpendicular to the first surface of the substrate.

11. The integrated circuit device of claim 9, wherein the upper backside metallization pattern includes a first upper backside metallization layer that comprises first ones of the interdigitated upper backside fingers, and a second upper backside metallization layer that comprises second ones of the interdigitated upper backside fingers,
wherein the first upper backside metallization layer is capacitively coupled to the second upper backside metallization layer, and
wherein the backside MOMCAP further comprises an insulating layer between the first upper backside metallization layer and the second upper backside metallization layer.

12. The integrated circuit device of claim 9, wherein the backside MOMCAP further comprises a lower backside metallization pattern on a lower surface of the upper backside metallization pattern, the lower backside metallization pattern including a plurality of interdigitated lower backside fingers, and
wherein the interdigitated lower backside fingers extend in the second direction and are spaced apart from each other in the first direction.

13. The integrated circuit device of claim 12, wherein the backside MOMCAP further comprises a backside insulating layer between the lower backside metallization pattern and the upper backside metallization pattern in a third direction perpendicular to the first surface of the substrate, and
wherein at least one of the interdigitated upper backside fingers overlaps at least one of the interdigitated lower backside fingers in the third direction.

14. The integrated circuit device of claim 8, further comprising a metal-oxide-semiconductor capacitor (MOSCAP) between the frontside MOMCAP and the backside MOMCAP,
wherein the MOSCAP comprises:
a lower semiconductor device on the substrate, the lower semiconductor device comprising a pair of lower source/drain regions and a lower gate structure between the pair of lower source/drain regions; and
an upper semiconductor device on the lower semiconductor device, the upper semiconductor device comprising a pair of upper source/drain regions and an upper gate structure between the pair of upper source/drain regions.

15. The integrated circuit device of claim 14, further comprising an upper source/drain contact structure that extends between the frontside MOMCAP and the backside MOMCAP, wherein a first one of the pair of upper source/drain regions is electrically connected to both the frontside MOMCAP and the backside MOMCAP through the upper source/drain contact structure.

16. The integrated circuit device of claim 14, further comprising a lower source/drain contact structure that extends between the frontside MOMCAP and the backside MOMCAP, wherein a first one of the pair of lower source/drain regions is electrically connected to both the frontside MOMCAP and the backside MOMCAP through the lower source/drain contact structure.

17. An integrated circuit device, comprising:
a substrate;
a metal-oxide-semiconductor capacitor (MOSCAP) on a first surface of the substrate; and
a backside metal-oxide-metal capacitor (MOMCAP) on a second surface of the substrate opposite the first surface, the backside MOMCAP electrically connected to the MOSCAP.

18. The integrated circuit device of claim 17, wherein the MOSCAP comprises:
a lower semiconductor device on the substrate, the lower semiconductor device comprising a pair of lower source/drain regions and a lower gate structure between the pair of lower source/drain regions; and
an upper semiconductor device on the lower semiconductor device, the upper semiconductor device comprising a pair of upper source/drain regions and an upper gate structure between the pair of upper source/drain regions.

19. The integrated circuit device of claim 18, further comprising a lower gate contact that extends into the substrate, wherein the lower gate structure is electrically connected to the backside MOMCAP through the lower gate contact.

20. The integrated circuit device of claim 18, further comprising a lower source/drain contact structure that extends into the substrate, wherein a first one of the pair of lower source/drain regions is electrically connected to the backside MOMCAP through the lower source/drain contact structure.
